(19) United States
(12) Patent Application Publication
(10) Pub. No.: US 2014/0366929 A1
(43) Pub. Date: Dec. 18, 2014

(54) SYSTEM AND METHOD FOR SOLAR ENERGY UTILIZATION

(71) Applicant: OR HAMA ENERGY LTD., Maaleh Adumim (IL)

(72) Inventor: Gilad Blau, Maaleh Adumim (IL)

(21) Appl. No.: 14/366,379

(22) PCT Filed: Dec. 17, 2012
(86) PCT No.: PCT/IL2012/050530

§ 371 Date: Jun. 18, 2014

(30) Foreign Application Priority Data
Dec. 18, 2011 (IL) 217059

(51) Int. Cl. H01L 31/052; H01L 31/042

(52) U.S. Cl. CPC H01L 31/0525; H01L 31/0422; H02S 40/00
USPC 136/246

(57) ABSTRACT

A system for solar energy utilization is described. The system comprises a solar receiver, a solar energy concentrator mounted on a pole extending from the solar receiver along the main axis of the system, and a solar tracking system. The solar receiver is configured for receiving solar energy from the sun and concentrating the received solar energy at a predetermined spot area. The solar receiver includes a plurality of flexible mirrors independent of each other and radially arranged around a main axis of the system. The flexible mirrors are configured to be either deployed for operation or collapsed, for example for transportation or in the cases of possible damage of the system. The solar energy concentrator is located at the predetermined spot area in which the solar energy reflected from said plurality of flexible mirrors is concentrated, and configured for converting the concentrated reflected energy into electric energy. The solar tracking system is configured for sensing position of the sun and tilting the system for directing the solar receiver towards the sun to receive and reflect maximum sunlight onto the predetermined spot area.

### FIELD OF THE INVENTION

This invention relates generally to system and methods for solar energy utilization, and more specifically to dynamic methods and apparatus for generation of electricity.

### BACKGROUND OF THE INVENTION

To date, there are two predominant kinds of solar systems, namely (a) thermal system based on a mirror focusing the sun's rays and producing energy via heat. This system is based on mirrors and is effective, but it is generally too costly; and a (b) photovoltaic (PV) system, which comprises photovoltaic cells, and which convert incident energy into electricity.

For example, U.S. Pat. Application No. 2012/0118351 describes a solar electricity generator including an array of photovoltaic power generating elements, and a single continuous smooth solar reflecting surface, the surface being arranged to reflect light from the sun onto the array of photovoltaic power generating elements.

U.S. Pat. Application No. 2011/0265852 describes an open concentrator system for solar radiation comprising a hollow mirror and a photovoltaic module comprising a plurality of solar cells disposed in the focus of said hollow mirror, the photovoltaic module being encapsulated by a housing. The housing is thereby configured such that it has a transparent cover at least in the region of the incident radiation reflected by the hollow mirror and such that this transparent cover is at a spacing from the photovoltaic module, i.e. is situated in the cone of the incident radiation.

It should be noted that these systems can be less effective than thermal systems, and often require more than seven years of electrical output to provide a return on investment (ROI). Thus, solar systems, despite their green advantages are not sufficiently economical, compared to conventional energy sources.

There is thus a need to provide economical, low-cost systems and methods for solar energy utilization.

### GENERAL DESCRIPTION OF THE INVENTION

Despite the prior art in the area of solar energy utilization techniques, there is still a need in the art for further improvement in order to provide a more economical and low-cost system and method for solar energy utilization.

There is also a need and it would be advantageous to have a light weight system for solar energy utilization

In some embodiments of the present invention, improved methods and apparatus are provided for utilizing solar energy in production of electricity.

The systems and devices of the present invention are constructed in the form of a flower, and this form is inspired by the shape and qualities of a living flower, whose petals or leaves are easily manipulated. Hereinafter the terms “petals” and “leaves” will be used interchangeably. According to an embodiment, the system includes a pole, a solar receiver mounted on the pole configured for reflecting and focusing the received solar energy, and a solar energy concentrator mounted on the pole at the location in which the solar energy that is reflected from the solar receiver is concentrated. Thus, as noted above, the pole resembles a flower stalk, the solar receiver resembles a flower corolla and includes a plurality of mirrors that resemble flower petals, whereas the solar energy concentrator resembles a flower pistil.

Each mirror leaf includes two main elements, such as an inflatable supporting element and a working element that covers the supporting element. The leaf is flexible, because both (supporting and working) elements are made of flexible materials.

Strings form parts of the supporting elements. The leaf shape can be flat or curved. The inflatable supporting element includes a valve connected by an air line to the air valve and by a common air line to the air pump. The supporting element has a spring-like ability because it is filled by pressurized or non pressurized gas.

The working element is formed by plates made of reflex foil. Concentric bedplates with locking mechanisms are stacked in layers.

The pole includes an upper central tube situated in the main axis of the device, attached to the bedplates. The leaf mirror has a lock mechanism opposite to the lock on the bedplate.

Once inflated, the leaf can be closely connected to the device. Clusters of leaves create a multi-layer working surface for the device. Multiple layers of leaves of equal size create a multi-focus area with a “dispersed” focus. Due to the centre of gravity point of the device, which is lower than a center of rotation and due to the device's construction being based on leaves with described attributes, the entire device is well-balanced and is naturally protected against outside forces when it is spread out and operational.

The folding mechanism is based on a pneumatic piston, which is coupled and pressurized through an air line to the air pressure tank with an electromagnetic air valve and by a common air line to the air pump. The piston is located on the top bedplate and actuates in the axis of the central tube.

The leaves can be closed at any time. Thus, the surface of the device can fold and shut. By folding and shutting the device, the leaves change to a compact shape with low aerodynamic profile which is greatly resistant to any outside forces.

A rotation mechanism based on a ball or a ball bearing is in the center of rotation. A tube going through the ball is terminated by two adapters and is situated beneath the bedplates. The device is connected by sheaths around the ball to legs or to cables. The upper central tube is connected to the upper adapter. A lower central tube is connected to the ball through the lower adapter.

The device can easily change the direction of the central tube about two axes due to the rotation mechanism. Three fluid tanks are connected symmetrically by an angle of 120° to the lower central tube. Inside the tanks is a fluid, whose movement induces a change in the direction of the direction vector.

Redirection can, for example, be achieved by pumping the fluid between the tanks and changing the center of gravity of the device. Pumping is produced by the air pump and can utilize the principle of an airlift. The fluid's destination is determined by a photovoltaic sensor on the top of the device. A microchip associated with sensor receives input from all connected sensors, manages the compressor, servos, electromagnets, etc. through many different processes. The microchip analyzes the appropriate time to fold and shut the device and drive the air pump to keep the necessary pressure in every part of the device as required.

According to some embodiments, the system includes a movement sensor that is responsible for active protection (closing) of the device during operation. Folding of the system can be carried out by a pneumatic piston mounted on the pole of the system. The central tube can convey cold air from the area below the surface of the corolla of the device, where the air is naturally cooler as a result of shadows created by the corolla surface of the device.

The solar concentrator is also referred to as a “crown” because of its shape and is situated on the top of the central tube of the pole. There could be various embodiments of a crown, based on different principles and technology.

In one case of utilization, the crown's surface catches sun rays prior to reaching a real focus and the crown's curvature and construction with air conduits create an airflow based on expansion of hot air and differences of temperature potentials, through the central tube. Photovoltaic (PV) plates can be inserted in the surface of the crown. These PV plates are able to transform the power of concentrated solar energy into electricity. The PV plates can be connected in parallel and/or serially into an electric circuit by conductors, e.g., wires. The DC power generated by the PV plates can be conducted to an inverter, that can be situated outside the system. The inverter is responsible for conversion DC power to AC power, synchronization of frequency and management of the supply of electricity to a grid.

It should be understood, that the system's lightweight construction that can, for example, weigh only a few kilograms, creates many opportunities, currently unavailable, for utilizing and placement of the system. The system can be installed on roofs, when the overlapping area of the roof also becomes a sunshade. The extended support pivots create a raised system suitable for installations in parks, fields, lawns, gardens, forests or hillsides etc. in harmony with the natural environment.

If the system is connected to carrying cables, one- or two-dimensional, vertical, horizontal or combined environmentally friendly installations can be created in cities, habitable areas, deserts, islands and oceans, etc.

Thus, the present invention partially eliminates disadvantages of conventional techniques solar energy utilization and provides a novel solar energy utilization system including a solar receiver, a solar energy concentrator mounted on a pole extending from the solar receiver along the main axis of the system, and a solar tracking system.

The solar receiver is configured for receiving solar energy from the sun and concentrating the received solar energy at a predetermined spot area. The solar receiver includes a plurality of flexible mirrors independent from each other and radially arranged around a main axis of the system. The plurality of the flexible mirrors is configured to be either deployed for operation or collapsed, for example for transportation or in the cases of possible damage of the system.

The solar energy concentrator is located at the predetermined spot area in which the solar energy reflected from said plurality of flexible mirrors is concentrated, and configured for converting the concentrated reflected energy into electric energy.

The solar tracking system is configured for sensing position of the sun in the sky and tilting the system for directing the solar receiver towards the sun to receive and reflect maximum of sunlight onto the predetermined spot area.

The solar receiver includes a hub having a plurality of disks arranged along the main axis of the system and suitable for holding the flexible mirrors. According to an embodiment, the hub includes an upper bedplate cover disk, a lower bedplate cover disk and a plurality of mirror holding disks sandwiched between the upper bedplate cover disk and the lower bedplate cover disk. The mirror holding disks are configured for securing and holding the flexible mirrors.

For example, the solar receiver may include three mirror holding disks and eighteen flexible mirrors arranged in three layers formed by the three holding disks. In this example, each mirror holding disk holds six flexible mirrors.

According to an embodiment, the solar receiver comprises a leaf locking mechanism configured for holding the flexible mirrors in the mirror holding disks. The mirror holding disks include a “female” part of the leaf locking mechanism securing the flexible mirrors in the radial positions around the main axis of the system. On the other hand, each flexible mirror includes a “male” part of the locking mechanism mating the “female” part arranged in the corresponding holding disks.

According to an embodiment, each female part includes a corresponding slit arranged in the holding disk. An inner surface of the slits includes at least one slit irregularity in a tooth shape. On the other hand, each flexible mirror comprises at least one corresponding leaf irregularity having a shape suitable to mate said at least one slit irregularity.

According to an embodiment, the solar receiver further includes a pneumatic mirror folding mechanism. The pneumatic mirror folding mechanism includes a movable ring mounted on the pole and capable to slide along the main axis of the system; folding strings attached to the flexible mirrors; and a pneumatic piston mounted on the top of the hub, and configured to lift the movable ring. The flexible mirrors can be folded in the radial direction toward the pole by lifting the movable ring up to pull the folding strings.

According to an embodiment, the folding mechanism includes an electromagnetic lock device mounted on the pole and configured to lock the movable ring, thereby holding the flexible mirrors in the folded state. The lock device can include an electromagnetic trigger configured for unlocking the lock device and releasing the movable ring.

According to an embodiment, the solar receiver includes an air tank coupled to the pneumatic piston via an air line including a controllable electromagnetic air valve. The pneumatic piston is activated by pressurized air passing from the tank after opening the controllable electromagnetic air valve.

According to an embodiment, the pneumatic piston includes a plurality of concentric tubes telescopically arranged along the main axis.

According to an embodiment, the system further includes an air controllable compressor coupled to the air tank for filling thereof with compressed air.

According to an embodiment, the air controllable compressor is coupled to the air tank via a multi-way gas flow control valve.

According to an embodiment, each flexible mirror includes an inflatable supporting member configured for connecting to the mirror holding disk, and a working member that is mounted on the inflatable supporting member.

According to an embodiment, the inflatable support element includes a flexible inflatable frame having a ladder shape and including inflatable radial beams fortified by a plurality of inflatable cross ribs. The inflatable supporting member of the flexible mirrors includes a leaf locking mechanism for securing an end part of the inflatable supporting member in the holding disks. The proximal end of the inflatable supporting member includes a nipple air valve configured for inflation of the flexible inflatable frame.

According to an embodiment, the system further includes a multi-functional controllable air compressor coupled to the inflatable supporting member for filling thereof.

According to an embodiment, the inflatable supporting member is enveloped by a fiber mesh for fortifying the supporting member. The inflatable supporting member is covered by radial shaping strings crossing the inflatable supporting member in radial directions and by circumferential shaping strings crossing the inflatable supporting member in the circumferential direction, which is perpendicular to the radial directions.

According to an embodiment, the shaping strings are interlaced with the fiber mesh along the radial direction, whereas the shaping strings are interlaced with the fiber mesh along the ribs. The shaping strings include SILON™ wire.

According to an embodiment, the inflatable supporting member further includes one or more folding strings attached to a distal end of the inflatable supporting member.

According to an embodiment, the inflatable supporting member includes guide tubes, which are attached to the fiber mesh at the foldable cross ribs and are configured to provided passage of the folding strings unrestrictedly therethrough.

According to an embodiment, the foldable cross ribs of the inflatable supporting member include a weakened longitudinal cross-section around which, the foldable cross ribs can kink or buckle to deform and move the radial beams towards each other.

According to an embodiment, the working member further includes a covering mesh attached to the top of the inflatable supporting member. The working member includes a plurality of flexible reflective plates attached to the covering mesh.

According to an embodiment, the flexible reflective plates are regularly arranged and overlap with each other, thereby filling completely the top surface of the working member. According to another embodiment, the flexible reflective plates are sparsely dispersed within the top surface of the working member. According to yet an embodiment, the flexible reflective plates are arranged in a fish scale fashion.

According to an embodiment, the flexible reflective plates are deflectable from the surface of the working member, thereby forming holes between the plates to enable an air stream to flow through these holes, and returning the flexible reflective plates to their operating position during the absence of the air stream. A space can be formed between flexible mirrors enabling an air stream, such as a mild wind to flow through the holes.

According to an embodiment, the solar receiver includes an air checking and filling mechanism configured for controllable checking pressure in the flexible inflatable frame of the flexible mirrors, and for filling the flexible mirrors with air when required, the air checking and filling mechanism includes a first multi-way air flow valve configured to supply air to the flexible inflatable frame. The first multi-way air valve is coupled to the air controllable compressor (via an air pipe connected to the compressor via a second multi-way air valve.

According to an embodiment, the solar receiver further includes a first servo configured for setting the first multi-way valve to supply pressurized air from the compressor to a selected flexible mirror.

According to an embodiment, the solar energy concentrator includes a substrate having a funnel shape with a wide conical substrate mouth with expansion towards a top end of the system, and a narrow stem including a sleeve connector mounted on the pole of the system. The substrate is axially symmetric and has a tapering angle of the conical part in the range of about 5 degrees to about 85 degrees with respect to an axis of the pole. The substrate has an outer surface configured for mounting solar photovoltaic (PV) elements thereon to generate electricity. For example, the solar photovoltaic (PV) elements can include arsenic-germanium-indium (AsGeIn) photovoltaic elements.

According to an embodiment, the solar energy concentrator includes an air-based cooling mechanism. For example, the cooling mechanism can include an inner coned tube mounted inside of the substrate. The inner coned tube is axially symmetric and has a diameter of a top of a conical mouth of the inner coned tube less than the diameter of the conical mouth of the substrate, thereby forming a circular slit between the substrate and the inner coned tube to form an air channel for cooling the photovoltaic elements. In the air channel, air passes from the area below the solar receiver, then through the pole and finally through the slit.

According to an embodiment, the cooling mechanism further includes a fan located along the air channel and configured to facilitate the air flow in the air channel.

According to an embodiment, the inner coned tube is mechanically connected to the substrate by means of connecting members. Examples of the connecting members include, but are not limited to, rods and plates in the shape of square brackets radially extending across the circular slit and attached to the walls of the inner coned tube and to the walls of the substrate.

According to an embodiment, a wall of the inner coned tube is wavy in shape and includes threads helically turning around the wall from both inner and outer sides of the inner coned tube. Thus a whirl effect for the air passing and exiting between the substrate and the inner coned tube is provided that enhances the cooling of the photovoltaic elements.

According to an embodiment, the cooling mechanism further includes an outer coned tube mounted outside of the substrate on a sleeve mounted on the pole. The outer coned tube is made from a material transparent to the light of the sun beams. The outer coned tube is axially symmetric and has a diameter of a top of a conical mouth of the outer coned tube greater than the diameter of the conical mouth of the substrate, thereby forming another circular slit between the substrate and the outer coned tube. This other circular slit provides another air channel for cooling the photovoltaic elements in addition to the air channel formed between the substrate and the inner coned tube.

According to an embodiment, the solar energy utilization system of the present invention further includes a pivot system for orienting the main axis of the system towards the sun. The pivot system includes a bearing socket integrated with sleeves having an opening configured for inserting installation members, and a thrust bearing arranged in the bearing socket. The thrust bearing includes a stationary outer race attached to the inner surface of the bearing socket and a movable inner race supporting the system at a pivot point located on the pole at a center of rotation of the system.

According to an embodiment, the solar tracking system includes three fluid communicating balance tanks extending from the main axis of the system in radial directions with an angle of 120 degrees between each pair of the tank directions. The three balance tanks contain liquid that is transferred between the tanks controllably via liquid communication tubes, thereby shifting the center of the mass of the system and tilting the main axis of the system in a desired direction.

According to an embodiment, the solar tracking system includes a second multi-way gas flow control valve coupled to an air compressor and configured for controllable providing air to one tank selected from the tanks to increase the pressure in the selected tank and thereby to push the liquid out from the selected tank into the other tanks.

According to an embodiment, the solar tracking system includes a second servo configured for setting the second multi-way air flow valve to supply air from the air compressor to a desired tank of the three tanks.

According to an embodiment, each tank of the solar tracking system includes a tank opening arranged at a distant end of the tank for releasing the excessive air. According to an embodiment, the solar tracking system includes an opening pipe arranged in each tank. The opening pipe has one pipe end connected to the tank opening and other pipe end is always kept above the level of the liquid. In order to support the other pipe end of the tank opening above the level of the liquid, the solar tracking system includes a float configured to float on the liquid inside each tank.

According to an embodiment, the solar tracking system includes a passing liquid pipe arranged in each tank and having one pipe end connected to the liquid communication tube and other pipe end being always kept below the level of the liquid. In order to keep the other pipe end always below the liquid level, the solar tracking system includes a sinker configured to be immersed in the liquid.

The solar energy utilization system includes an air compressor configured for providing pressurized gas for activation of folding the mirrors and tracking the sun.

According to an embodiment, the solar receiver includes the following controllable devices: an electromagnetic trigger configured for unlocking the flexible mirrors when the mirrors are in a folded state; an electromagnetic valve configured for providing compressed air for folding the flexible mirrors, a first servo associated with a first multi-way valve and configured for setting the first multi-way valve to supply pressurized air from the compressor to a selected flexible mirror for filling the selected mirror with air when required, a second servo associated with a second multi-way air flow valve and configured for setting the second multi-way air flow valve to supply air from the compressor to the solar tracking system, and a fan configured for providing air for cooling the solar tracking system.

The solar energy utilization includes a control system configured for control of the operation of the system. The control system includes a power supply unit configured to provide electric power required for operation of electric and electronic modules of the system and at least one sensor selected from the group consisting of: a output voltage sensor configured for measuring the output voltage generated by the system; a motion sensor configured for detecting moving objects in the vicinity of the system that might be potentially hazardous for the system; a sun tracking sensor configured for recognizing the location of the sun; a mirror pressure sensor configured for measuring the air pressure that is required for deploying the solar receiver; a power voltage sensor configured for measuring the power supply voltage provided by the power supply unit; and an output voltage sensor configured for measuring output voltage generated by the solar energy concentrator.

The control system includes a controller coupled to at least one of the sensors and configured for analyzing the received sensor data and generating control signals to the controller connector switch to controllably provide electric power supply voltages from a power supply unit to at least one device selected from the group consisting of: the electromagnetic trigger, the electromagnetic valve, the first servo, the second servo, the air compressor, and the fan, thereby to control operation of the system.

According to another aspect of the present invention, there is provided a novel method for dynamic solar energy utilization. The method includes receiving and concentrating solar energy from the sun by a solar receiver configured for receiving solar energy from the sun; converting the concentrated energy into direct current electricity by a solar energy concentrator being located at the predetermined spot area in which the solar energy reflected from said plurality of flexible mirrors is concentrated.

The method further includes sensing position of the sun in the sky by a solar tracking system and tilting the solar receiver for directing thereof towards the sun to receive and reflect maximum of sunlight onto the predetermined spot area.

According to an embodiment, the method further includes passing cooling air through a solar energy concentrator.

According to an embodiment, the method further includes folding at least one of said plurality of flexible mirrors under unfavorable environmental conditions.

According to an embodiment, the method further includes deploying at least one of said at least one of said plurality of flexible mirrors under favorable environmental conditions.

According to an embodiment, the method further includes inverting said DC electricity to AC electricity and providing said AC electricity into an electricity grid.

The system of the present invention is a “green device” because it is ecologically friendly in various aspects during its entire life cycle. It is designed and constructed to reach parity in comparison with conventional fossil fuel sources of energy; and is able to produce electricity at a lower cost than other forms of energy, thus effectively breaking the parity with other energy sources. Benefits of the system include, but are not limited to low cost, usage of small amount of materials, relatively low energy consumption for the production process, relatively low weight of the device, a compact shape in a collapsed state, easy installation, noiseless and harmless operation, high resistance to harmful air conditions and factors, such as rain, snow, dew, wind, sand, dust, insects etc., seldom malfunctioning with relatively easy maintenance, and long service periods of proper functioning, modular construction with easy replacement of impaired parts, recyclable at the end of the system life cycle, etc.

It is to be understood that the invention is not limited in its application to the details set forth in the description contained herein or illustrated in the drawings. The invention is capable of other embodiments and of being practiced and carried out in various ways. Those skilled in the art will readily appreciate that various modifications and changes can be applied to the embodiments of the invention as hereinbefore described without departing from its scope, defined in and by the appended embodiments.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1A is a perspective sliced view of a system for solar energy utilization in a deployed (outspread) position, in accordance with an embodiment of the present invention;

FIG. 1B is a hub for securing and holding flexible mirrors of the solar receiver of the system shown in FIG. 1A, in accordance with an embodiment of the present invention;

FIG. 1C is a exploded top view of the mirror holding disk and the flexible mirrors of the solar receiver of the system shown in FIG. 1A, in accordance with an embodiment of the present invention;

FIG. 1D is a schematic simplified diagram of a control system of the system of FIG. 1A, in accordance with an embodiment of the present invention;

FIG. 1E is a perspective view of a system for solar energy utilization in a collapsed position with folded flexible mirrors, in accordance with an embodiment of the present invention;

FIG. 2 is a bottom part of the system shown in FIG. 1A, in accordance with an embodiment of the present invention;

FIGS. 3A-3C are partial perspective sliced cross-sectional views of the system of FIG. 1A during operation of a pneumatic piston, in accordance with an embodiment of the present invention;

FIG. 4, an exploded view of the flexible mirror of the system shown in FIG. 1A is illustrated, in accordance with an embodiment of the present invention;

FIGS. 5A-5D show the steps of folding the inflatable supporting member of the flexible mirror shown in FIG. 4 in the circumferential and radial directions;

FIG. 6 illustrates an example of passive protection of the flexible mirrors of the system shown in FIG. 1A against wind, in accordance with an embodiment of the present invention;

FIG. 7 illustrates another example of passive protection of the flexible mirrors of the system shown in FIG. 1A against wind, in accordance with an embodiment of the present invention;

FIGS. 8A-8D illustrate further examples of passive protection of the flexible mirrors of the system shown in FIG. 1A against wind, in accordance with different embodiments of the present invention;

FIG. 9 is a portion of the system shown in FIG. 1A responsible for deployment and maintenance of the flexible mirrors, in accordance with an embodiment of the present invention;

FIG. 10A is a schematic optic diagram for the sun beams for a concave mirror;

FIG. 10B is a schematic optic diagram for the sun beams for the flexible mirrors of the system shown in FIG. 1A, in accordance with an embodiment of the present invention;

FIG. 11 is a perspective sliced cross-sectional view of the solar energy concentrator of the system shown in FIG. 1A, according to an embodiment of the present invention;

FIGS. 12A and 12B show correspondingly front and side views of the photovoltaic elements of the solar energy concentrator shown in FIG. 1A, according to an embodiment of the present invention;

FIG. 13 is a perspective sliced cross-sectional view of the solar energy concentrator of the system shown in FIG. 1A, according to another embodiment of the present invention;

FIG. 14 is a perspective partial sliced cross-sectional view of the system for solar energy utilization of FIG. 1A, illustrated with amplification of certain fragments, according to an embodiment of the present invention;

FIGS. 15 and 16 show perspective sliced cross-sectional views of the solar tracking system of the system of FIG. 1A, illustrated with amplification of certain fragments, according to an embodiment of the present invention;

FIG. 17A illustrates an example of installation of the system of FIG. 1A on a roof area;

FIG. 17B illustrates an example of installation of the system of FIG. 1A on legs;

FIG. 17C illustrates an example of installation of the system of FIG. 1A on public lampposts;

FIGS. 18A and 18B illustrate simplified schematic illustrations of installation of a plurality of the system of FIG. 1A on various cable systems for vertical and horizontal installations, correspondingly, in accordance with an embodiment of the present invention;

FIGS. 19A and 19B are simplified schematic illustrations of vertical and horizontal configuration of cables, correspondingly, on which a plurality of the systems of FIG. 1A is mounted, in accordance with various embodiments of the present invention;

FIGS. 20A and 20B show position of installation cables when altitude directions of the system of FIG. 1A are varied in a broad range of tiling angles;

FIG. 21 shows a flow chart schematically illustrating a method for converting solar energy into electric energy, into heat energy or reflecting light with the system of FIG. 1A, in accordance with an embodiment of the present invention;

FIG. 22 is a simplified flowchart of a method for cooling the solar energy concentrator of the system of FIG. 1A, in accordance with an embodiment of the present invention;

FIG. 23 is a simplified flowchart of a method for active protection of the system (10 in FIG. 1A) from moving subjects, in accordance with an embodiment of the present invention;

FIG. 24 is a simplified flowchart of a method for tracking the sun's movement, in accordance with an embodiment of the present invention; and

FIG. 25 is a simplified flow chart of a method for positioning the system of FIG. 1A, in accordance with an embodiment of the present invention;

### DETAILED DESCRIPTION

The principles and operation of a system and method for solar energy utilization according to the present invention may be better understood with reference to the drawings and the accompanying description. It should be understood that these drawings are given for illustrative purposes only and are not meant to be limiting. It should be noted that the figures illustrating various examples of the system of the present invention are not to scale, and are not in proportion, for purposes of clarity. It should be noted that the blocks as well other elements in these figures are intended as functional entities only, such that the functional relationships between the entities are shown, rather than any physical connections and/or physical relationships. The same reference numerals and alphabetic characters will be utilized for identifying those components which are common in the imaging system and its components shown in the drawings throughout the present description of the invention.

In practical applications of solar energy, based on the use of sun rays as the source of energy, in order to attain the highest economical benefits the surface of the device should be as large as possible and clean. Sun tracking in two axes (azimuthally and altitudinally) during the entire period of operation increases utilization to the maximum. In the current known forms of devices, heretofore devised or proposed, dust and other pollutants cleave to their static surface and are unavoidable.

In various exemplary embodiments, the present invention provides systems and methods for collecting and converting solar energy into electrical energy, collecting and converting solar energy into heat for subsequent utilization and collecting and reflecting solar energy for subsequent utilization.

The system of the present invention differs from the existing solar systems, which incorporate a great amount of materials and mechanics resulting in limitations on placement. Also a great deal of maintenance, heavyweight and numerous defects and limitations add to complication and costs.

The object of the present invention is to overcome these deficiencies and to effect the usage of solar energy in a more perfect manner and by a simpler and more economical means than those heretofore employed.

This is accomplished by a lightweight dynamic support system, enabling keeping a shape to a reflex operational surface and by a solar receiver equipped with a passive and active air-based self-cooling mechanism. Together the system is provided with a passive (elastic) and active (folding and shutting) self protection ability.

It is well known that a flower head/corolla protects itself by shutting petals. Treetops resist gusts of wind by fragmentation of their canopy mass to many leaves and by the treetop's aerodynamic shape. The water in an aquarium is pumped by a compressor utilizing, for example, an airlift or other suitable techniques.

The device is built from light weight and highly resistant materials, developed and used earlier for construction of space satellites. The price of these materials has dropped rapidly over the past years, and these materials are now mass produced at low cost. If it is not explicitly described in the text then the connection of materials is performed by welding.

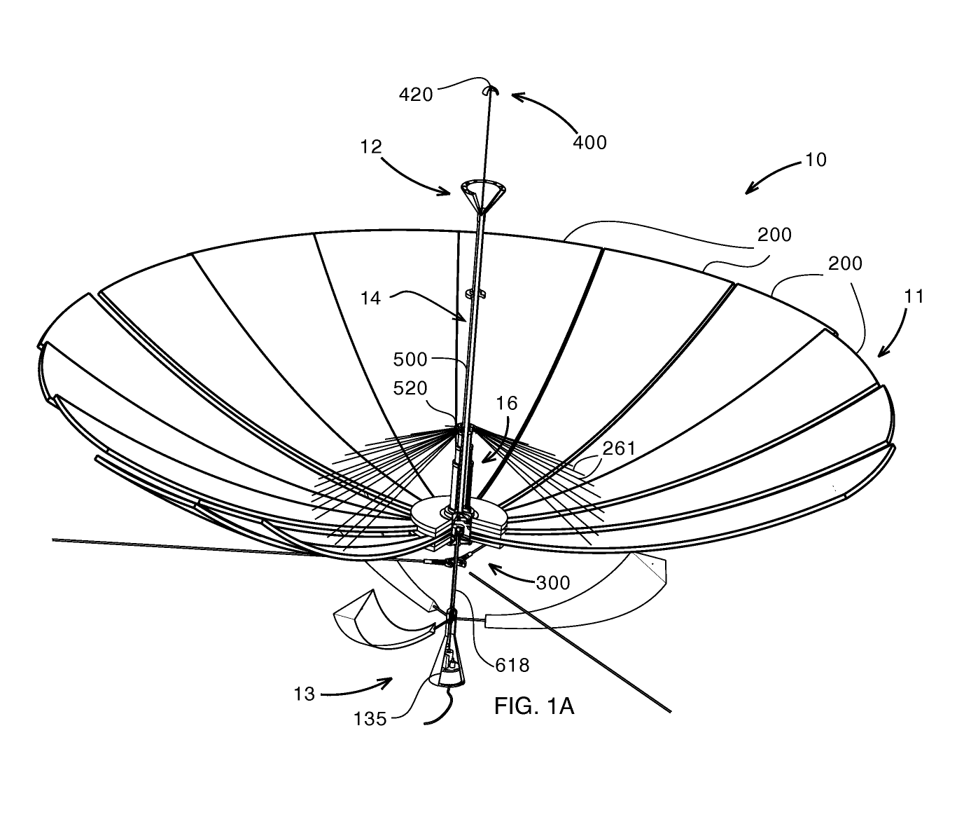

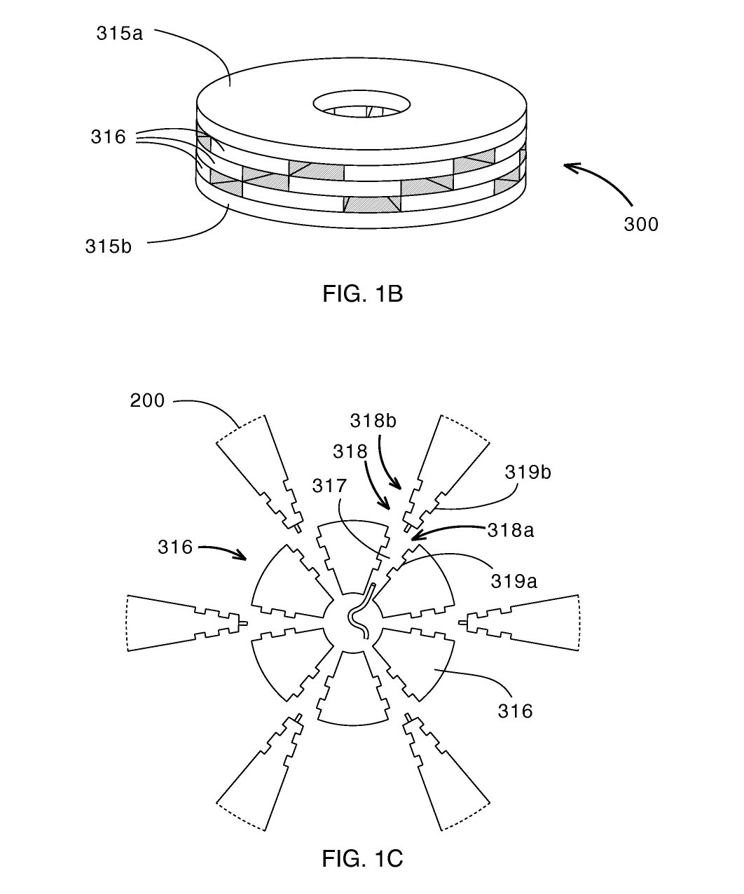

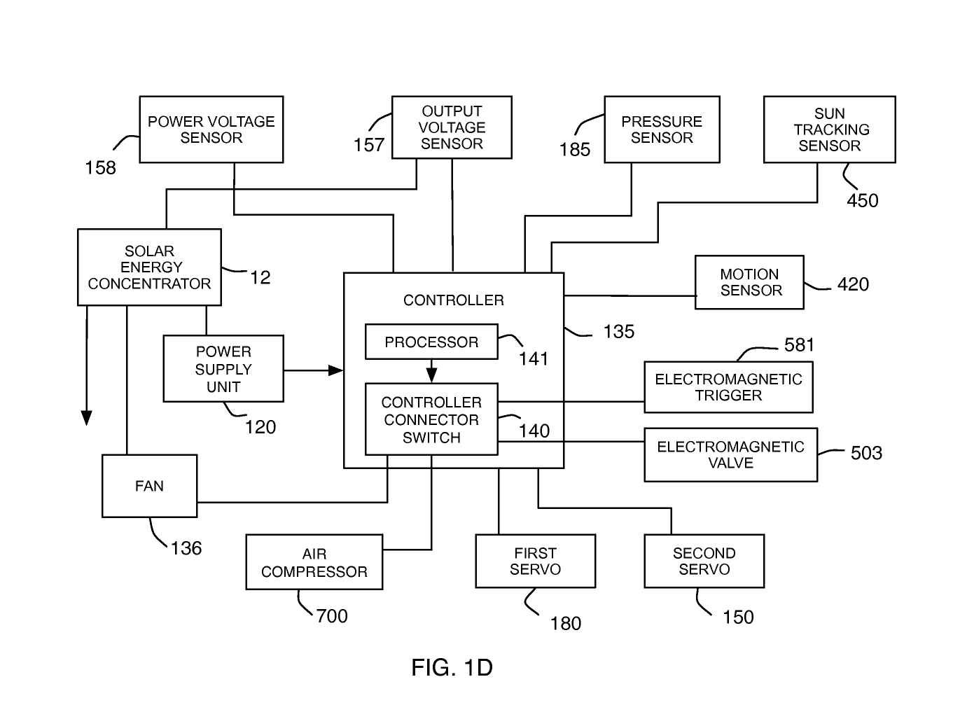

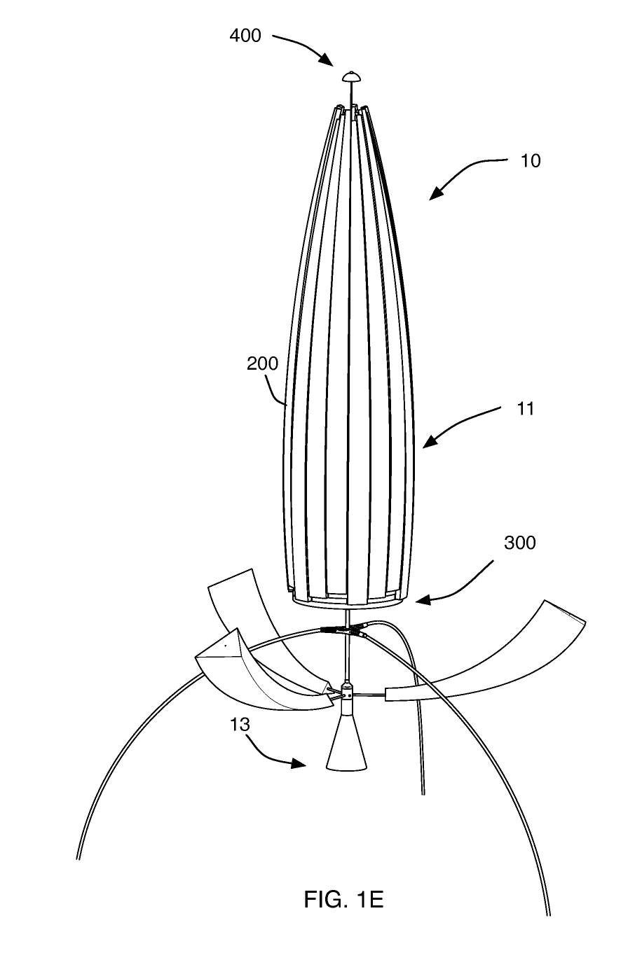

Reference is now made to FIG. 1A, which is a perspective sliced view of a system 10 for solar energy utilization in a deployed (outspread) position, in accordance with an embodiment of the present invention. The system 10 includes a solar receiver 11 configured for receiving solar energy from the sun and concentrating the received solar energy at a fixed predetermined spot area. For example, the concentration can be between 80-fold to 300 fold. The system 10 also includes a solar energy concentrator 12 located at the predetermined spot area in which the solar energy is concentrated, and configured for converting the concentrated reflected energy into a direct current electric power. The system 10 further includes a solar tracking system 13 associated with the solar receiver 11 and configured for sensing position of the sun in the sky and tilting the system 10 for directing the solar receiver 11 towards the sun to receive and reflect maximum of sunlight onto the spot area.

Referring to FIG. 1A, FIGS. 1D and 1E together, the system 10 includes a control system 15 that can be set to control the operation of the system 10 either automatically or manually. The control system 15 includes such known components and utilities as various sensing devices and a controller 135 having, inter alia, a processor 141, a power supply unit 120, and a controller connector switch 140.

According to an embodiment, the control system 15 includes an output voltage sensor 157, a motion sensor 420, a sun tracking sensor 450, a mirror pressure sensor 185, and a power voltage sensor 158. The output voltage sensor 157 measures the output voltage generated by the system 10. The motion sensor 420 is configured to detect moving objects in the vicinity of the system that might be potentially hazardous for the system 10. The sun tracking sensor 450 is responsible for recognizing the location of the sun. The mirror pressure sensor 185 measures the air pressure that is required for deploying the solar receiver 11. The power voltage sensor 158 measures the power supply voltage provided by the power supply unit 120 and required for operation of electric and electronic devices of the system 10. The output voltage sensor 157 measures the output voltage generated by the photo-voltaic elements, i.e., solar cells, (not shown) of the solar energy concentrator 11.

The processor 141 of the controller 135 is preprogrammed by a suitable software model capable of analyzing the received sensor data and generating control signals. The power supply unit 120 is based on power capacitors (not shown) configured to receive electric power from the solar energy concentrator 11. The electrical capacitance of these power capacitors can, for example, be in the range of about 15 F to 40 F.

The described above sensors 157, 158, 185, 450 and 420 are electrically coupled to the controller 135 and configured to provide the controller 135 with the corresponding sensor signals. In turn, the controller 135 is configured for receiving the data provided by the sensing devices 157, 158, 185, 450 and 420, processing these data and generating control signals to a controller switch 140 to activate various operating modules of the system, such as an electromagnetic trigger 581, an electromagnetic valve 503, a first servo 180, a second servo 150, a multifunctional controllable air compressor 700, and to a fan 136. In operation, the controller connector switch 140 is controlled by the processor 141 and configured to provide corresponding power supply voltages from a power supply unit 120 to the electromagnetic trigger 581, the electromagnetic valve 503, the first servo 180, the second servo 150, the air compressor 700, and to the fan 136 as will be described hereinbelow in detail through the description.

The power supply unit 120 is sensed by the power voltage sensor 158, and is electrically charged when the voltage measured by the power voltage sensor 158 is less than a predetermined power supply voltage, for example less than 20% of the nominal voltage.

The power supply unit 120 and the controller 135 can be independent modules connected to a common board with slots (backboard) and thus has easily changeable parts in case of malfunction. The processor unit includes an output/input interface to enable a connection to a mobile device or radio module. This additional electronic equipment enables wireless metering of the wattage generated, uploading new firmware, downloading device data, direct custom settings and direct controlling of the device etc.

The system 10 can include an AC inverter (not shown) responsible for managing wattage and frequency suitable for the grid. The AC inverter can be either integrated with the system 10 or be a dedicated module located out of the system 10.

Although in the embodiment shown in FIG. 1A the controller 135 is located at a bottom part B of the system 10, generally, the controller 135 can be located at any suitable place, which is protected from being affected by harsh environment.

According to the embodiment shown in FIG. 1A, the solar receiver 11, the solar energy concentrator 12 and the solar energy concentrator 12 are mounted on a pole 14 defining a main axis and a longitudinal axial direction of the device. The pole 14 includes several rods and tubes as will be described hereinbelow, and configured for holding the solar receiver 11 and the solar energy concentrator 12 at the predetermined spot area.

The solar receiver 11 resembles a flower corolla and includes a plurality of flexible mirrors 200, which resemble flower petals or leaves. The flexible mirrors 200 are configured to take in a deployed state or a collapsed state, as desired. The flexible mirrors 200 are separated and independent from each other, and are radially arranged around the main axis of the system. The flexible mirrors 200 are independent from each other in the sense that each of these mirrors of the solar receiver 11 can be replaced without replacing any other mirror. For example, the diameter of the receiver corolla can be in the range of one to six meters and even more.

During operation, the flexible mirrors 200 can be fully deployed to capture maximum solar energy. However, at night, in the case of harsh outside factors, such as debris, insects, dust, dirt, etc. or when the weather conditions are not appropriate for operation, such as rain storm, dew, etc., the solar receiver 11 can be collapsed to maintain the flexible mirrors 200 of the of the solar receiver 11 in a folded state close to the pole 14. As shown in FIG. 1E, when the mirrors 200 are in a folded state, the collapsed system 10 can be easily transported and stored.

The solar receiver 11 includes a hub 300 including a plurality of disks arranged along the main axis of the system and coupled to a central tube 500 of the pole 14. The disks of the hub 300 are made from a rigid material suitable for holding the flexible mirrors 200 in the collapsed and deployed states. Example of the material includes, but is not limited to, STYROFOAM™.

Referring to FIG. 1B, the hub 300 includes an upper bedplate cover disk 315a, a lower bedplate cover disk 315b and a plurality of mirror holding disks 316 sandwiched between the upper bedplate cover disk 315a and the lower bedplate cover disk 315b. The mirror holding disks 316 are configured for securing and holding the flexible mirrors 200.

According to the embodiment shown in FIGS. 1A and 1B, the corolla of the solar receiver 11 includes eighteen flexible mirrors 200, however other numbers of the flexible mirrors 200 are also contemplated. The flexible mirrors 200 are arranged in three layers formed by the holding disks 316, differentiated by hatching.

Referring to FIG. 1C, an exploded top view of the mirror holding disk 316, and the flexible mirrors 200 is shown, according to an embodiment of the present invention. Each mirror holding disk 316 holds six flexible mirrors 200, however, generally the disks 316 may hold any number of the flexible mirrors 200. Since the flexible mirrors 200 are located in a multi layer fashion, each layer of the mirrors 200 has its own geometric focus, thus providing a dispersed concentration of mirrored beams on the surface of the solar energy concentrator 12 as will be described hereinfurther in detail.

The solar receiver 11 includes a leaf locking mechanism 318 configured for holding the flexible mirrors 200 in the mirror holding disks 316. According to an embodiment, the mirror holding disks 316 include a “female” part 318a of the leaf locking mechanism 318 securing the flexible mirrors 200 in the radial positions around the pole (14 in FIG. 1A). For this purpose, each flexible mirror 200 includes a “male” part 318b of the locking mechanism 318 mating the “female” part 318a arranged in the corresponding holding disks 316.

According to this embodiment, each female part 318a of leaf locking mechanism 318 includes a corresponding slit 317 arranged in the body of the holding disk 316. As shown in FIG. 1C, the inner surface of the slits 317 is not even, but rather includes one or more slit irregularities 319a in the shape of teeth. On the other hand, each flexible mirror 200 includes corresponding leaf irregularities 319b having a shape suitable to mate the slit irregularities 319a.

The flexible mirrors 200 can be folded at any time. Thus, the surface of the solar receiver 11 can be collapsed. By folding, the mirrors 200 change shape to be compact with a low aerodynamic profile, which can provide protection from harsh outside factors, such as strong wind, debris, insects, dust, dirt, rain, dew, snow, and other unfavorable weather conditions that can impact the system during exploitation.

Turning back to FIG. 1A, in order to fold up the flexible mirrors 200 in the radial direction, the solar receiver 11 includes a movable ring 520 mounted on the central tube 500 of the pole 14 and capable to slide along the main axis of the system defined by the pole 14, folding strings 261 attached to the flexible mirrors 200. As can be seen in FIG. 1A, the flexible mirrors 200 are connected by folding strings 261 to the movable ring 520 slidable along the central tube 500 of the pole 14. The folding strings 261 can, for example, be made from fishing wire. When desired, the flexible mirrors 200 can be folded in the radial direction toward the pole 14 by moving the movable ring 520 up toward the concentrator 12, and thereby pulling the folding strings 261.

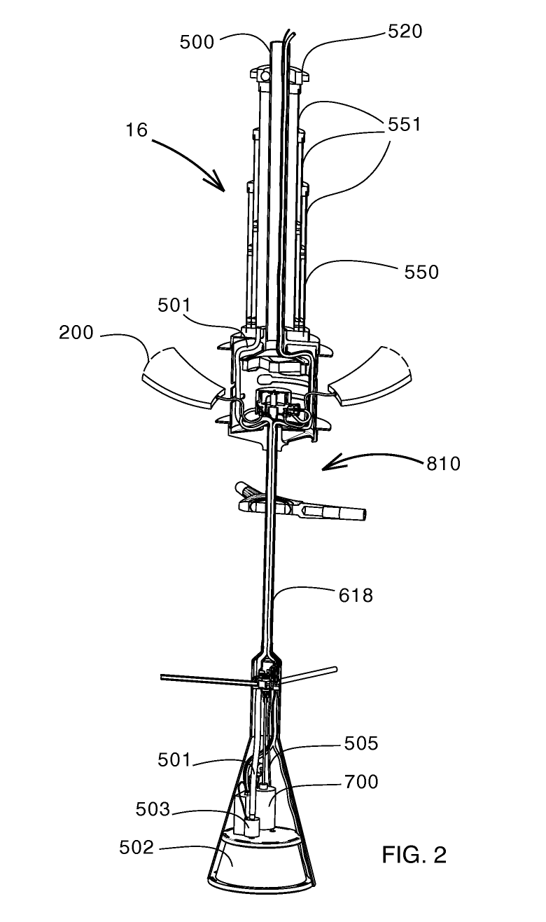

According to an embodiment, vertical motion of the movable ring 520 is activated by turning on a pneumatic mirror folding mechanism 16. Referring to FIG. 2, the pneumatic folding mechanism 16 includes a pneumatic piston 550, which is connected and pressurized through a piston air line 501 passing through a lower tube 618 to an air tank 502 via a controllable electromagnetic air valve 503. The pneumatic piston 550 includes a plurality of concentric tubes 551 telescopically arranged along the main axis on the central tube 500. It should be understood that although three telescopically arranged concentric tubes 551 are shown in FIG. 2, generally, the pneumatic piston 550 can include any suitable number of the concentric tubes 551. The hub 300 is mounted in a housing 94. The piston 550 is mounted on the top of the housing 94.

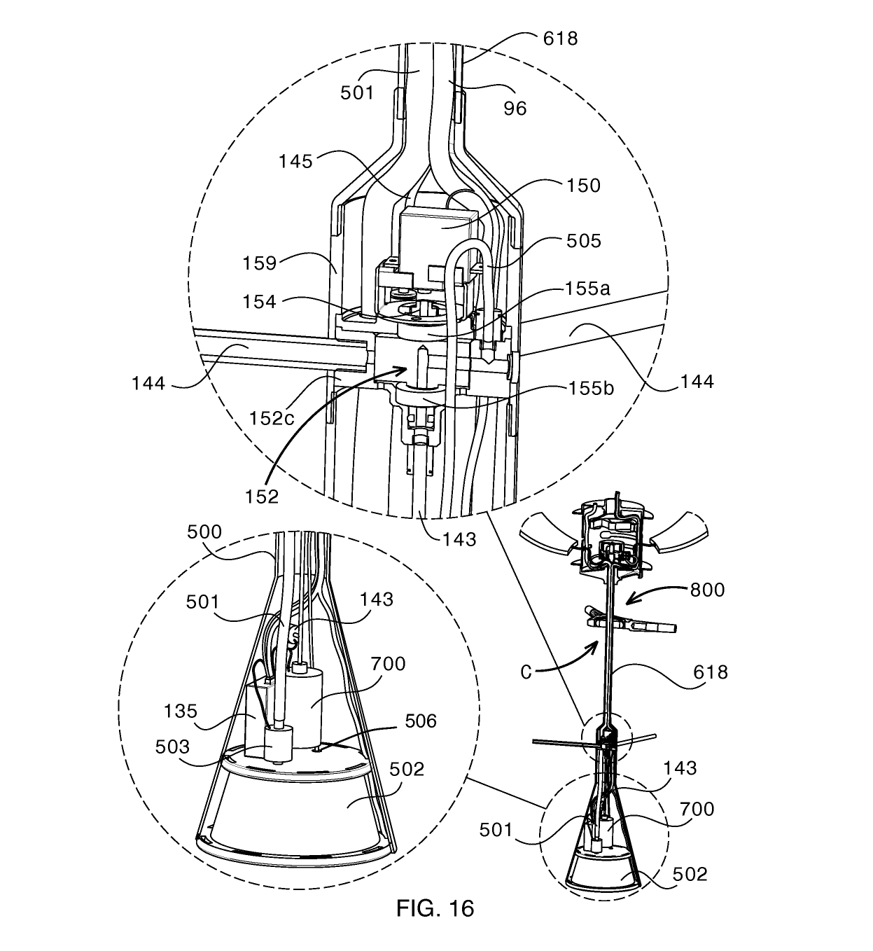

According to some embodiments, the system 10 for solar energy utilization of the present invention includes multifunctional controllable air compressor 700. One of the functions of the multifunctional controllable air compressor 700 is to fill, inter alia, the air tank 502 with atmospheric air. Other functions of the compressor 700 will be described hereinbelow. According to an embodiment, the air tank 502 can be coupled to the compressor 700 directly. According to another embodiment, the air tank 502 can be coupled to the compressor 700 via a multi-way gas flow control valve, in particular via the five-way air valve 152, as will be described hereinbelow with reference to FIG. 16.

As shown in FIG. 1A and FIG. 2, the air tank 502 and the compressor 700 are arranged at a bottom part B of the system 10; however other implementations are also contemplated.

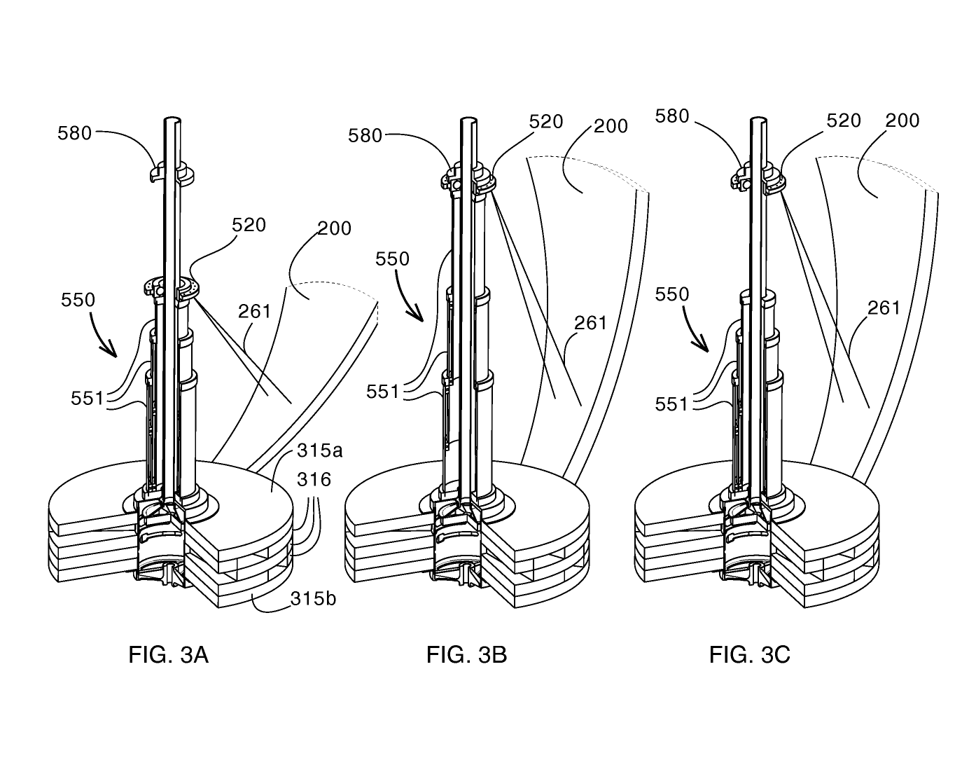

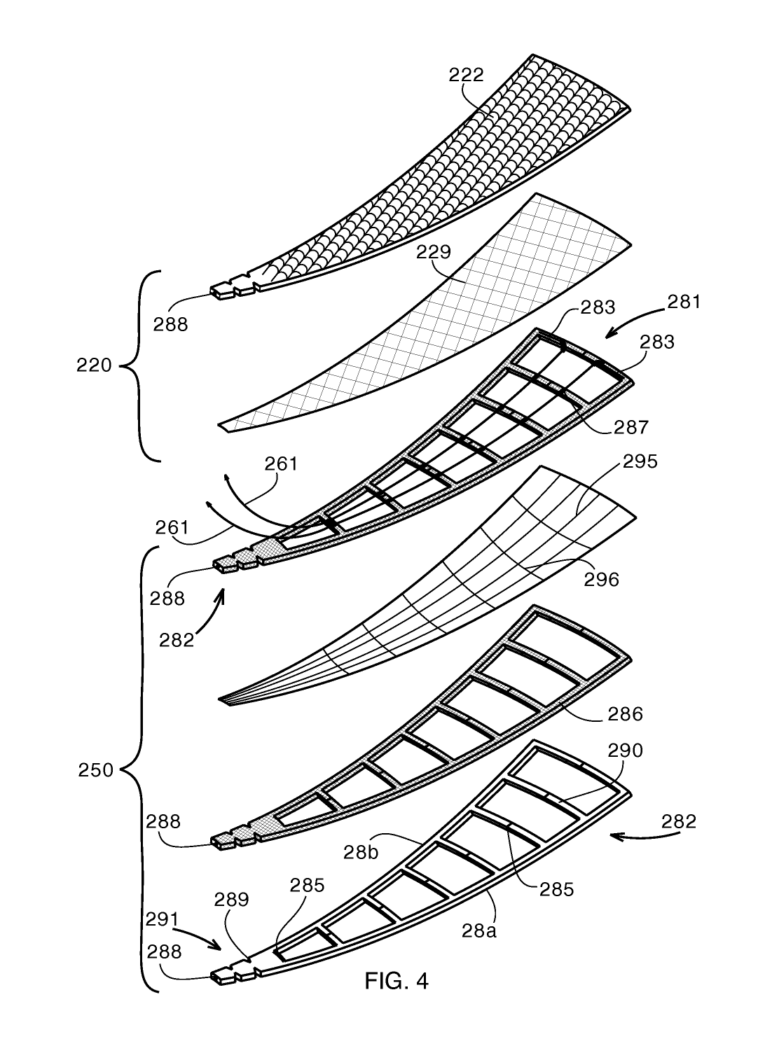

Reference is now made to FIGS. 3A-3C together, which are partial perspective sliced cross-sectional views of the system (10 in FIG. 1A) during operation of the pneumatic piston 550, in accordance with an embodiment of the present invention. As shown, the pneumatic piston 550 can operate in the three main phases. In the first phase, the flexible mirrors 200 are deployed in the open default position (see FIG. 3A). According to the present invention, the flexible mirrors 200 can be opened due to the spring-like features of the flexible mirrors 200. An example of the construction of the flexible mirrors 200 providing such properties will be described hereinbelow in detail with reference to FIG. 4. This provision provides a spread out shape of the flexible mirrors 200 in a deployed state.

In operation, when the external factors or harsh weather conditions may prevent normal operation of the system, the control system (135 in FIG. 1A) provides a folding control signal to the electromagnetic air valve 503 for opening thereof. The folding control signal can, for example, be generated in response to sensor signals indicative of such harsh factors and conditions. For this purpose, the control system 135 includes sensors configured for sensing such harsh factors and conditions and for generating corresponding sensor signals indicative of the factors and conditions preventing normal operation of the system 10.

As shown in FIG. 1D, the control system 15 includes the movement sensor 420 configured for detecting moving objects, such as a bird or other flying object in the vicinity of the system, that might be potentially hazardous. The movement sensor 420 can, for example, be arranged on a hemisphere 400 mounted on a top of the system 10, however other locations are also contemplated. The control system 15 includes the output voltage sensor 158. Thus, when the voltage generated by the system 10 significantly decreases, this may be a result of rain, wind storm, dirt storm, etc. The controller 135 responsive to the drop of the output voltage, can generate a control system to open the valve 503.

Referring to FIGS. 1D and 3A-3C together, when the valve 503 is open, it enables air to pass from the air tank 502 to the pneumatic piston 550 through the piston air line (501 in FIG. 2). The pressure pulse provided by the air passing from the air tank 502 expands the pneumatic piston 550 by unfolding its telescopic tubes 551. Since the movable ring 520 sits on the top of the pneumatic piston 550, the expansion of the piston 550 provides sliding of the movable ring 520 along the central tube 500. In turn, the flexible mirrors 200, which are connected to movable ring 520 via the folding strings 261, can follow the ring 520 and thereby fold, thus overcoming the spring's resistance of the mirrors 200. As will be described hereinbelow, this spring's resistance can provide unfolding of the flexible mirrors 200.

According to some embodiments, the folding mechanism 16 includes an electromagnetic lock device 580 mounted on the central tube 500 of the pole 14. In the second phase, as shown in FIG. 3B, the movable ring 520 reaches the lock device 580, where it can be locked, thereby holding the flexible mirrors 200 in the folded state. The locking of the movable ring 520 within the lock device 580 can, for example, be carried out by mechanical locking.

Upon delivering the movable ring 520 to the electromagnetic lock device 580, after a certain time period, the piston 550 can be returned in the folded state under gravity, due to the release of the air in the piston and corresponding decrease of pressure within the piston. As shown in FIG. 3C, the movable ring 520 is retained by the electromagnetic lock device 580 as long as desired, thereby maintaining the system 10 in the collapsed state. The electromagnetic lock device 580, can, for example, include a mechanical latch (not shown) for locking the movable ring 520.

In order to deploy the folded system 10, the lock device 580 includes an electromagnetic trigger (584 in FIG. 1D) which after activation unlocks the lock device 580 and thereby releases the movable ring 520. The electromagnetic trigger can be controlled by the control system 135 responsive either to a user's instruction or to a sensor signal generated by a sensing device indicating that the harsh outside factors or bad weather conditions are over and the system can be deployed for operation. For example, the movement sensor can provide the corresponding sensor signal. When desired, the system may include a set of other sensors (not shown), such as a rain sensor, a storm sensor and/or a dirt sensor that can generate the corresponding signals indicative that the harsh outside factors or bad weather conditions are over and the system can be deployed for operation.

As soon as the lock device 580 is unlocked, the flexible mirrors 200 unfold due to the spring-like feature of the mirrors, and the movable ring 520 returns to the top of the piston.

It should be understood that after activation of the pneumatic piston 550, pressure in the air tank 502 drops. In order to raise this pressure for the next piston activation and folding the mirrors, the compressor 700 can be activated at any moment after piston activation. It should be noted that when the compressed air stored in the tank 502 may be sufficient for several activation cycles of the pneumatic piston 550 without filling of the tank 502.

Referring to FIG. 4, an exploded view of the flexible mirror 200 is illustrated, in accordance with an embodiment of the present invention. The flexible mirror 200 includes an inflatable supporting member 250 configured for connecting to the mirror holding disks (316 in FIGS. 1A-1C) and a working member 220 that is mounted on the inflatable supporting member 250. The flexible mirrors 200 are flexible, since the inflatable supporting element 250 and the working element 220 are both made of flexible materials. It should be understood that inflatable supporting member 250 and the working member 220 can be constructed from various materials with many shapes and colors.

The inflatable support element 250 includes a flexible inflatable frame 282 having a ladder shape and including inflatable radial beams 28a and 28b fortified by a plurality of inflatable cross ribs 290. The flexible inflatable frame 282 can be fabricated of a relatively stiff yet somewhat pliant material, sufficient to hold the working member 220 when the flexible mirrors 200 are expanded in a deployed state. For example, the flexible inflatable frame 282 can be constructed from a composite material containing a metal folia layer covered from outer and inner sides by plastic layers (e.g., polyvinylchloride (PVC) layers) or from some other suitable relatively strong and light materials.

The inflatable supporting member 250 of the flexible mirrors 200 includes the locking mechanism (318a in FIG. 1C) for securing an end part 291 of the inflatable supporting member 250 in the holding disks (316 in FIGS. 1B and 1C). The proximal end 291 of the inflatable supporting member 250 includes a nipple air valve 288 configured for inflation of flexible inflatable frame 282. The air for inflation of the inflatable supporting member 250 can be provided from a compressor (700 in FIG. 1A) through an air line 701, as will be described hereinfurther in detail.

It should be understood that the described provision of connection of the flexible mirrors 200 to the holding disks 316 enables easy maintenance and repair of an impaired flexible mirror. Indeed, by deflating the inflatable supporting member 250, a damaged flexible mirror 200 can be easily removed from the disk 316 and replaced by a faultless mirror.

According to an embodiment, the inflatable supporting member 250 is enveloped by a fiber mesh 286 for fortifying the supporting member 250. The mesh can, for example, be made from a strong material providing fortification to the inflatable supporting member 250 to withstand high pressure of the gas filling the inner cavity of the inflatable supporting member 250. For example, the fiber mesh 286 can be a metalized mesh with diameter of the filaments in the range of 15 micrometers to 30 micrometers.

According to an embodiment, the inflatable supporting member 250 is covered by radial shaping strings 295 crossing the inflatable supporting member 250 in radial directions and by circumferential shaping strings 296 crossing the inflatable supporting member 250 in the circumferential direction, which is perpendicular to the radial directions. The shaping strings 295 can, for example, be attached to or interlaced with the fiber mesh 286 along the radial direction, whereas the shaping strings 296 can be attached to or interlaced with the fiber mesh 286 along the ribs 290. The shaping strings 295 and 296 enable the inflatable supporting member 250 to take and maintain a desired petal shape. An example of the material suitable for the shaping strings 295 and 296 includes, but is not limited to SILON™ wire having a diameter in the range of about 30 micrometers to 500 micrometers.

In order to fold up the flexible mirrors 200 of the solar receiver 11 in the radial direction, the inflatable supporting member 250 further includes one or more folding strings 261 attached to the distal end 281 of the inflatable supporting member 250 and to the movable ring (520 in FIG. 1A) mounted on the central tube (500 in FIG. 1A) of the pole (14 in FIG. 1A) and capable to slide along the pole 14.

The folding strings 261 can, for example, be made from fishing wire having a diameter in the range of 0.3 millimeters to 1 millimeter. The folding strings 261 pass radially from the distal end 281 towards the locking end 282 within the inflatable supporting member 250 unrestrictedly through guide tubes 287, which are attached to the fiber mesh 286 at the foldable cross ribs 290. When desired, the inflatable supporting member 250 (and accordingly the flexible mirrors 200) can be folded in the radial direction by activating the piston 550 that moves up the movable ring 520 that accordingly pulls the folding strings 261, as described above with reference to FIGS. 3A-3C.

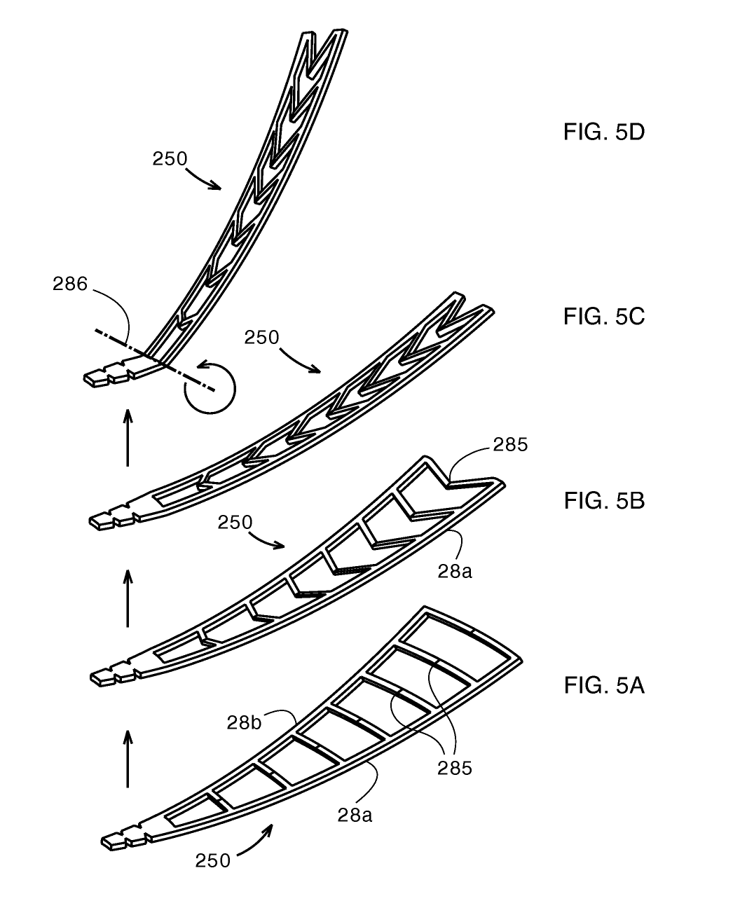

According to an embodiment, in order to decrease the surface of the flexible mirrors 200, the inflatable supporting member 250 can be folded not only in the radial direction but also in the circumferential direction, which is orthogonal to the radial direction. FIGS. 5A-5D show the steps of folding the inflatable supporting member 250 in the circumferential direction (see FIGS. 5A-5C) and thereafter in the radial direction (see FIG. 5C).

Thus, for folding in the circumferential direction, the foldable cross ribs 290 of the inflatable supporting member 250 include a weakened longitudinal cross-section 285. As shown sequentially in FIGS. 5A-5C, the foldable cross ribs 290 can kink or buckle around this weakened longitudinal cross-section 285 to deform and move the radial beams 28a and 28b towards each other. Then, the mirrors can be folded in the radial direction as shown in FIG. 5C around a weakened transverse cross-section 286 to be close to the pole 14, thereby decreasing their sailing properties that can be required in the case of a strong wind preventing operation of the solar energy utilization system of the present invention.

Turning back to FIG. 4, the working member 220 is mounted on the inflatable supporting member 250 and creates a covering layer for the upper side of the inflatable supporting member 250. The working member 220 includes a covering mesh 229 attached to the top of the inflatable supporting member 250. The mesh 229 is fabricated of a somewhat pliant material, which permits to fold the flexible mirrors 200. An example of the material suitable for the mesh 229 includes, but is not limited to SILON™ wire having a diameter in the range of 10 micrometers to 300 micrometers.

The working member 220 also includes a plurality of flexible reflective plates 222 attached to the covering mesh 229. The flexible reflective plates 222 may vary in size, shape, structure and extent.

According to an embodiment, the flexible reflective plates 222 can be regularly arranged and overlap with each other, thereby to fill completely the top surface of the working member 220. Alternatively, flexible reflective plates 222 can be sparsely dispersed within the top surface of the working member 220. An example of the material suitable flexible reflective plates 222 includes, but is not limited to, a metalized foil such as MYLAR™ that achieves reflexivity up to 99.9% efficiency. A thickness of the foil can, for example, be in the range of 10 micrometers to 25 micrometers.

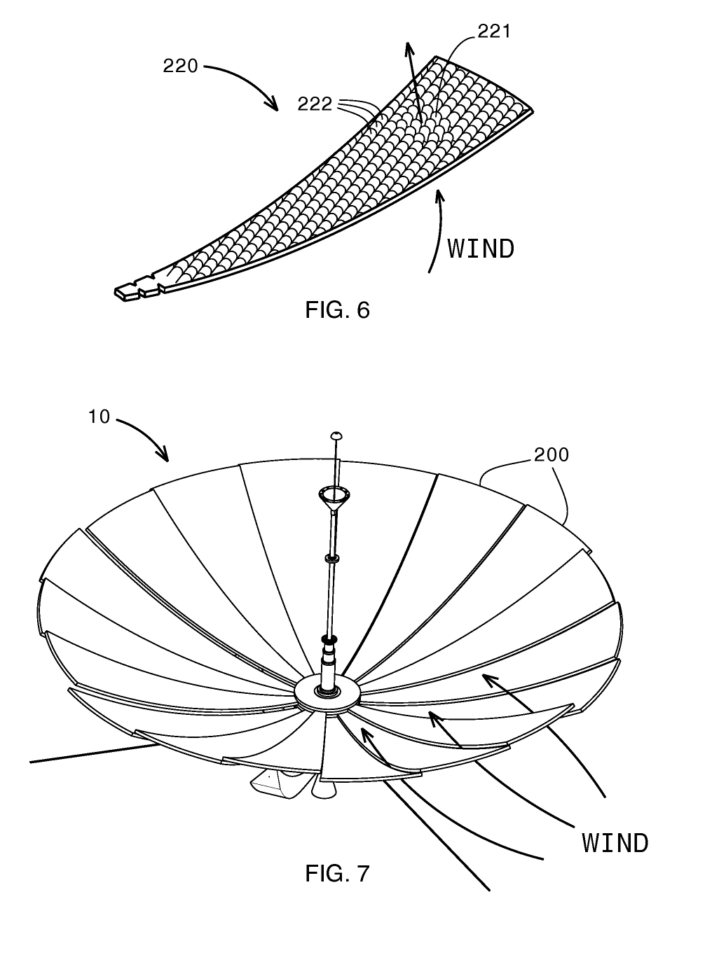

Referring to FIG. 6, an example of the working member 220 is shown when the flexible reflective plates 222 are arranged in a fish scale fashion. The reflective plates 222 resemble a fish scale. Due to their flexibility, the plates 222 can be deflected from the surface of the working member 220 to form holes 221 between the plates 222 enabling an air stream, e.g., wind, to flow through these holes. When the wind subsides, the plates 222 can return to their operating position owing to their flexible properties. This kind of protection of the mirrors (200 in FIG. 1A) is herein referred to as “passive fish scale protection”.

During operation, the system of the present invention is in a deployed position, in which the flexible mirrors 200 are spread out. In this case, protection against dust, insects, etc. can be required. For this reason, the construction of the flexible mirror 200 permits a few types of passive protection.

Reference is now made to FIG. 7, in which another example of simplified schematic passive protection of the flexible mirror 200 is illustrated, in accordance with an embodiment of the present invention. Since the system 10 includes independent separate flexible mirrors 200, natural protection against a relatively mild wind can be achieved. Thus, the arrows shown in FIG. 7 illustrate the wind flow through the spaces between the mirrors 200. This kind of protection of the mirrors 200 is herein referred to as “daisy protection”.

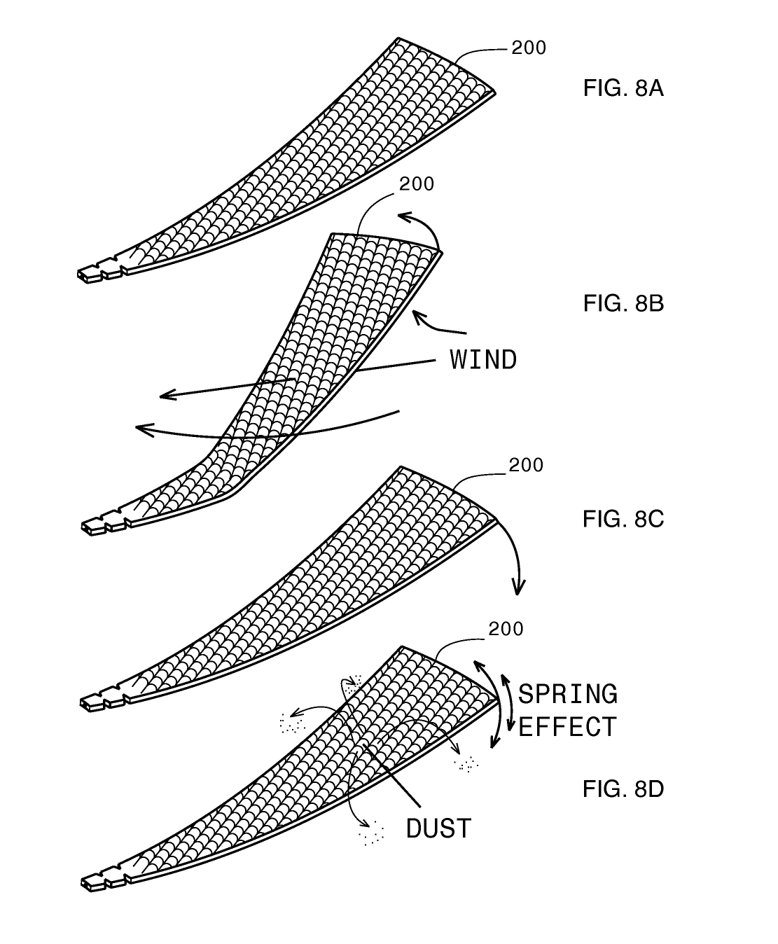

Reference is now made to FIGS. 8A and 8B, in which simplified schematic illustrations of a further example of passive protection of the mirrors 200 are illustrated, in accordance with an embodiment of the present invention. This protection is required with a further increase of wind strength. When the quantity and speed of the flowing air increases, and it can be so large that the air mass cannot flow through the spaces between leaves and cannot flow through the holes in the mirrors 200, the flexible mirror 200 can be deflected from the basic operational position shown in FIG. 8A, and a gust of wind blowing against the surface of the flexible mirror 200 can thrust the leaf up shown in FIG. 8B. Thus, the flexible mirror 200 can be flexed by the wind. As soon as the gust subsides, the inflatable supporting member 250 can operate as a spring and thus can return the flexible mirror 200 to its fully open operational position, as a result of the flexibility properties (see FIG. 8C). Due to this oscillating movement (see FIGS. 8C and 8D), the energy of the wind applied to the mirror 200 can be dissipated. This process can, for example, be compared to the oscillation of leaves in palm treetops during wind insufflations. This kind of protection is herein referred to as “passive palm tree protection”.

It shown in FIG. 8D, the flexible mirror 200 pivoted at one end will oscillate as a spring pendulum. The consecutive swinging with lessening amplitude creates leaf shaking. As a result of the corresponding vibrations dust and or debris collected on the mirror 200 can fall down from the mirror's surface. This type of protection of protection of the mirrors 200 is herein referred to as “Passive dust protection”.

It should be understood that all the described kinds of mirrors' protection are passive in the sense that they do not require any special input of the user during these protection activities.

The closing of each mirror 200 can be sequential by opposite pairs of mirrors, as a result of different lengths of the folding strings 261. Thus each layer of the mirror leaves can close separately, also sequentially from the highest mirror layer to the lower mirror layer. The closing of each leaf follows a given spring resistance point of the previous leaf. This presents a lesser demand on force generated by the closing mechanism air piston 550. The closing process of packing of the supporting segments, minimizes the leaf size, which enables maintaining the device's shape, compacts leaves together, and forms the narrow, conical shape.

Dew and dust are extremely dangerous for surfaces of solar devices. In the presence of dew, before or during sunrise, the sun's power is weak, the air temperature is low and the wind is rising. The wind starts throwing up dust, and the dust, together with the dew, create ooze which overlays the surface. When the sun begins to shine, the ooze creates a crust, which is almost impossible to remove without scratching the surface of common solar devices. As will be described below, the present invention utilizes an active self protection ability based on folding and shutting at the right time and keeping a narrowly conical compact closed shape of the mirrors with an extremely low aerodynamic profile, avoiding any potential danger to the system.

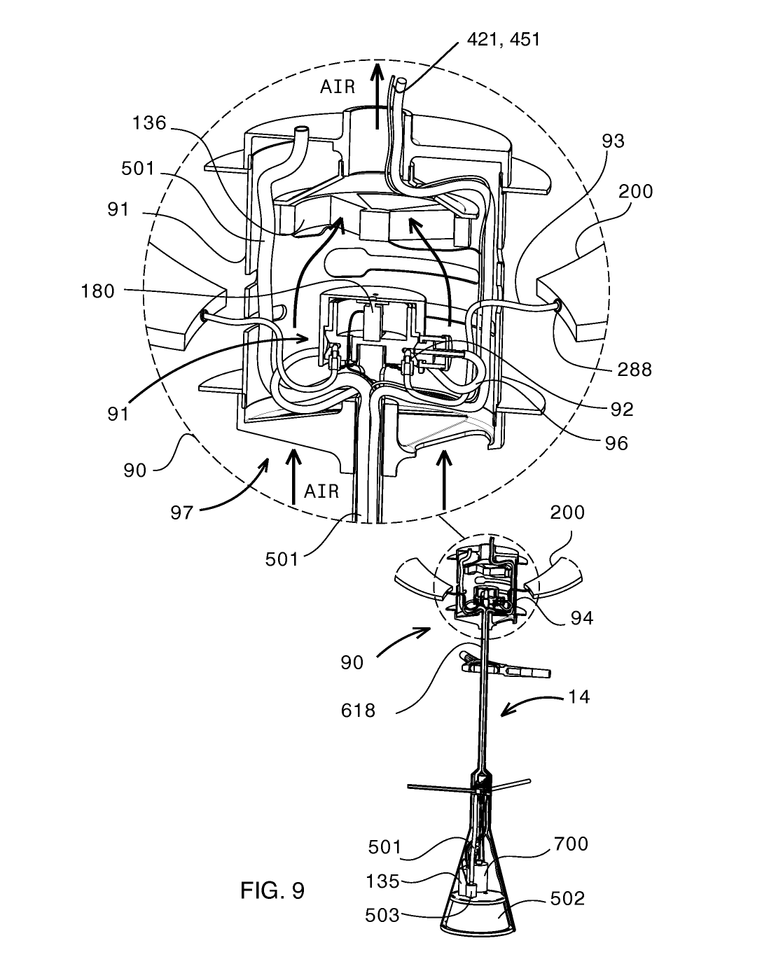

Referring to FIG. 9, the solar receiver 11 further includes an air checking and filling mechanism 90 for controllable checking pressure in the flexible inflatable frame (282 in FIG. 4) of the flexible mirrors, and for filling the flexible mirrors 200 with air when required. The air checking and filling mechanism 90 includes a first multi-way air flow valve 91 mounted in the hub 300 and configured to supply air to the flexible mirrors 200. The first multi-way air valve 91 is coupled to the multifunctional compressor 700 via an air pipe 96. According to an embodiment, the air pipe 96 can be directly connected to the compressor 700. According to another embodiment, the air pipe 96 can be coupled to the compressor 700 via a second multi-way air valve (in particular to the five-way air valve 152, as will be described hereinbelow with reference to FIG. 16).

The compressor 700 is, inter alia, responsible for supplying and maintaining pressurized air inside the flexible inflatable frame (282 in FIG. 4) of the flexible mirrors. The multi-way valve 91 includes nozzles 92, each nozzle coupled to the corresponding nipple air valve 288 of the flexible inflatable frame (282 in FIG. 4) via a filling tube 93. A number of the nozzles 92 equals to the number of the flexible mirrors 200. Thus, since the solar receiver 11 shown in FIGS. 1A-1C includes 18 flexible mirrors 200, the first multi-way valve 91 is an 18-way air valve.

The solar receiver 11 further includes a first servo 180 configured for setting the first multi-way valve 91 to supply pressurized air from the compressor 700 to a selected flexible mirror 200.

Referring to FIG. 9 and FIG. 1D together, the air checking and filling mechanism 90 is controlled by the control system 15 that includes the mirror pressure sensor 185 associated with the first multi-way valve 91 and configured for measuring pressure in the flexible inflatable frame (282 in FIG. 4) of the mirrors 200. In operation, the mirror pressure sensor 185 is coupled one by one to each of the mirrors 200 for measuring pressure therein. When the pressure sensor 185 is coupled to a certain mirror 200, it generates a pressure signal indicative of the pressure therein. When the pressure is within the required limits, the controller 135 can generate a control signal for the connector switch 140 to activate the first servo 180 for coupling the pressure sensor 185 to a neighboring mirror 200 for measuring the pressure therein. On the other hand, if the pressure in the checked mirror 200 is less than a predetermined pressure value, the controller 135 can generate a control signal for the connector switch 140 to activate the compressor 700 for filling the flexible inflatable frame (282 in FIG. 4) with the air up to the predetermined pressure value.

If the flexible inflatable frame is broken, the pressure during the filling with air will not change, nor increase, with the required rate. In this case, the controller 135 can generate a warning signal to the user of the system 10 to repair the system and replace the impaired mirror.

According to an embodiment of the present invention, the air checking and filling mechanism 90 is arranged in the housing 94 mounted in the hub (300 in FIG. 1A), which is connected to the top end of the lower tube 618 and to the bottom end of the central tube 500 of the pole 14. The housing 94 defines a chamber that includes, inter alia, the multi-way valve 91 and the first servo 180. The housing 94 also provides a frame on which the disks of the hub (300 in FIG. 1A) are mounted.

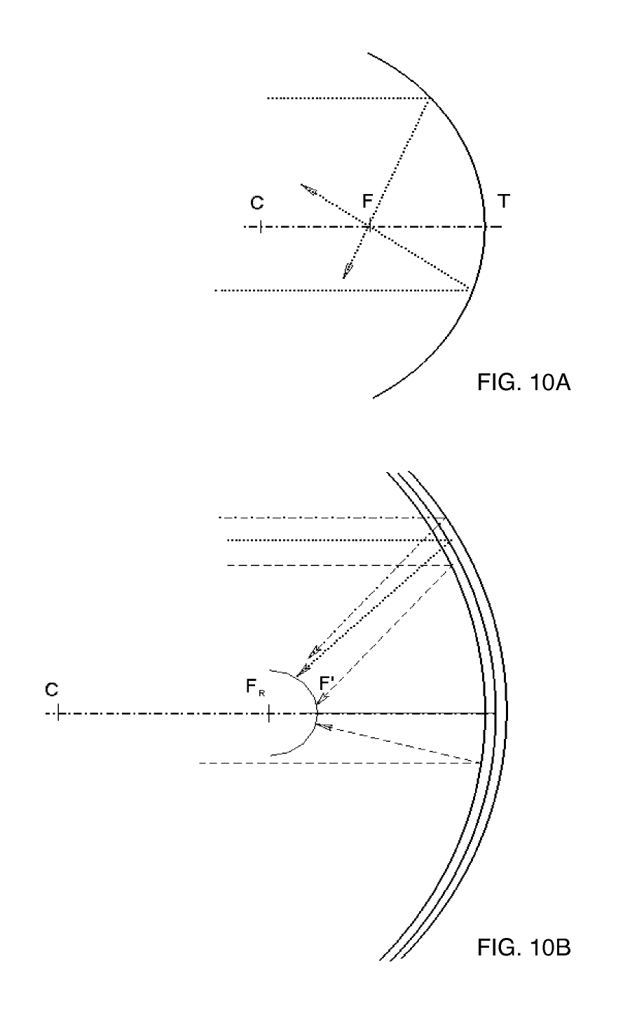

Reference is now made to FIG. 10A, which is a schematic optic diagram for the sun-beams for a concave mirror 101. The mirror 101 can, for example, be spherical or parabolic. The mirror 101 is assumed to be rotationally symmetric about the principal axis that is normal to the centre of the mirror. Hence, a three-dimensional mirror can be represented in a two-dimensional diagram, without loss of generality. The point T at which the principal axis touches the surface of the mirror is called the vertex. The point C, on the principal axis, which is equidistant from all points on the reflecting surface of the mirror, is called the centre of curvature. The distance along the principal axis from point C to point T is called the radius of curvature of the mirror. It is assumed that rays striking a concave mirror parallel to its principal axis, and not too far away from this axis, are reflected by the mirror such that they all pass through the same point F on the principal axis. This point, which lies between the centre of curvature and the vertex, is called the focal point, or focus, of the mirror. The distance along the principal axis from the focus to the vertex is called the focal length of the mirror. However, this is only an approximation, since when all light-rays which strike a mirror parallel to their principal axis (e.g., all rays emanating from the sun), and are brought to a focus at the same point, this is valid only for a parabolic mirror. It turns out in practice that as rays from a distant object depart further from the principal axis of a concave mirror they are brought to a focus even closer to the mirror. This lack of perfect focusing of a spherical mirror is called spherical aberration.

Reference is now made to FIG. 10B, which is a schematic optic diagram for sunbeams for flexible mirrors 200, in accordance with an embodiment of the present invention. Due to the fact that the flexible mirrors 200 are mounted to the holding disks stacked in layers, each layer of the mirrors 200 has its own geometric focus, thus providing a multi-focus area with dispersed concentration of mirrored beams on the principal axis. As described above, such dispersion can also be facilitated by spherical aberration, owing to the non-parabolic surface of the flexible mirrors 200. Accordingly, there is a certain area around a point F_{R} that is referred herein to as an “increased focus” F′. The use of the increased focus has advantages over the “point focus” F_{R}. For instance, since the sun rays are concentrated on larger surfaces of the increased area of focus, the high temperature is not concentrated at one point. Moreover, it is easier to cool the area of the “increased focus” F′. Accordingly, this area of increased focus is used in the system 10 for location of the solar energy concentrator 12.

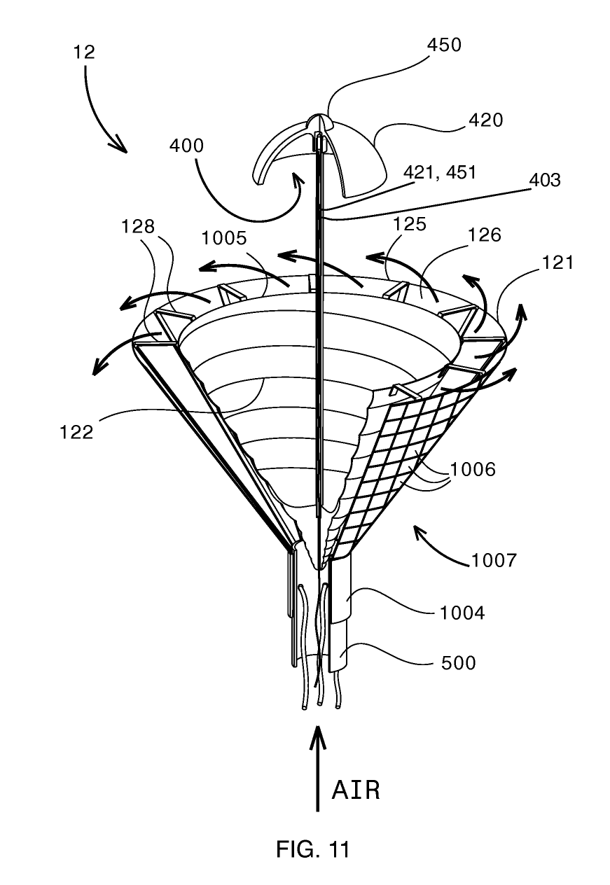

Reference is now made to FIG. 11, in which a perspective sliced cross-sectional view of the solar energy concentrator 12 is illustrated, according to an embodiment of the present invention. The solar energy concentrator 12 is arranged at the top of the system (10 in FIG. 1A) at the predetermined location, where the solar energy reflected from the mirrors 200 is concentrated. The solar concentrator resides on the top of the upper tube 500 and is therefore also referred to as a “crown”. The solar energy concentrator 12 includes a substrate 121 having a funnel shape with a wide conical substrate mouth 122 with expansion towards the top end of the system, and a narrow stem including a sleeve connector 1004 mounted on the top of the central tube 500. The solar energy concentrator 12 placed as a crown on the top of the upper central tube 500 by an overlapping sleeve connector 1004, can be easily interchangeable, when required.

According to an embodiment, the substrate 121 is axially symmetric and has a tapering angle of the conical part in the range of about 5 degrees to about 85 degrees with respect to an axis of the pole (14 in FIG. 1A). The expansion can start from the top of the central tube 500, however other embodiments are contemplated. It should be understood that the expansion towards the top end can be either symmetric or asymmetric with respect to the pole 14.

The substrate 121 has an outer surface 1007, which is used for mounting solar photovoltaic (PV) elements 1006 thereon to generate electricity. The substrate 121 can for example be made from a light and relatively strong material suitable to provide support to solar photovoltaic (PV) elements 1006. Examples of the materials suitable for the substrate 121 include, but are not limited to, aluminum (Al), titanium (Ti), copper (Cu), etc.

The photovoltaic elements on the outer surface 1007 can be arranged in lines and rows. Examples of PV elements suitable for the purpose of the present invention include, but are not limited to, arsenic-germanium-indium (AsGeIn) photovoltaic elements, crystalline silicone (c-Si), carbon, etc. In particular, it was shown that three thin layer plates formed from AsGeIn photovoltaic elements are able to work with efficiency better than 40%. In turn, a theoretical calculation for a five layers PV cell fabricated from AsGeIn shows that efficiency can reach up to 86%. The photovoltaic elements on the outer surface 1007 can, for example, provide at least 0.4 KW/m² of solar energy-receiving leaves of mirrors.

The photovoltaic elements 1006 can be modular components that can be interchangeable in cases where an impaired element should be replaced with a working element.

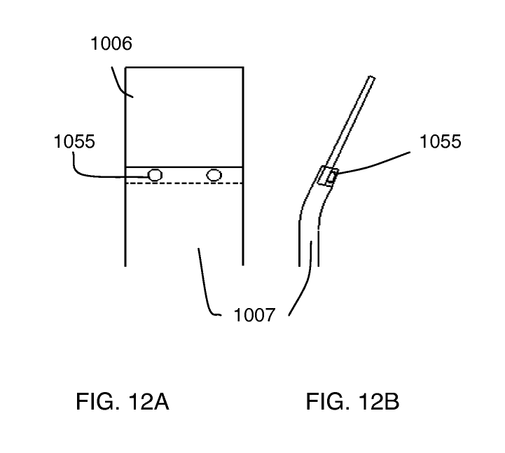

Reference is now made to FIGS. 12A and 12B, which show front and side views of the photovoltaic elements 1006, correspondingly, and a manner of attachment of the elements 1006 to the outer surface 1007, in accordance with an embodiment of the present invention. The photovoltaic elements 1006 can, for example, be welded to the surface 1007 at one end or screwed or to the surface 1007 at one end by using two or more bolts 1055, as shown FIGS. 12A and 12B. Alternatively, the photovoltaic elements 1006 can be welded to the outer surface 1007 at their entire rear side.

Referring to FIGS. 9 and 11 together, the solar energy concentrator 12 is equipped with an air-based cooling mechanism. This cooling mechanism operates passively up to the solar concentration of 30 suns and does not require a motor or any other turbine inside the upper central tube 500. When the solar concentration is greater than 30 suns, the cooling becomes active using a fan as described below. It should be noted that the air-based cooling system of the present invention utilizes natural atmospheric air for cooling, and it thus avoids a heavy and expensive cooler since the cooling medium is atmospheric air available in unlimited quantities.

According to an embodiment of the present invention, the cooling mechanism includes an inner coned tube 1005 mounted inside of the substrate 121. Examples of the materials suitable for the inner coned tube 1005 include, but are not limited to, aluminum (Al), titanium (Ti), copper (Cu), etc.

The inner coned tube 124 is axially symmetric and has a tapering angle of the conical part in the range of about 5 degrees to about 85 degrees with respect to an axis of the pole (14 in FIG. 1A). A diameter of a top of a conical mouth of the inner coned tube 1005 is less than the diameter of the conical mouth 125 of the substrate 121, thereby forming a circular slit 126 between the substrate 121 and the inner coned tube 1005. The circular slit 126 provides an air channel for cooling the photovoltaic elements 1006. The air channel is formed for passing air from the area below the solar receiver 11 through upper tube 500 of the pole 14 and through the slit 126 for cooling the photovoltaic elements 1006.

According to an embodiment, the inner coned tube 1005 is mechanically connected to the substrate 121 by means of connecting members 128. The connecting members can, for example, include rods or plates in the shape of square brackets radially extending across the circular slit 126 and attached to the walls of the inner coned tube 1005 and to the walls of the substrate 121.

In operation, the atmospheric air from the area under the flexible mirrors 200 enters through an opening 97 at the bottom of the housing 94, passes through the housing 94, and through the upper central tube 500, and then through the circular slit 126. The cooling mechanism of the solar energy concentrator 12 also includes a fan 136 located at a top of the housing 94 to enhance air flow from the area under the flexible mirrors 200 to the circular slit 126. When desired, a speed of the fan can be controlled by the controller (135 in FIG. 1D) on the basis of the sensor signal provided by the output voltage sensor (157 in FIG. 1D).

According to an embodiment of the invention, a wall 122 of the inner coned tube 1005 is wavy in shape, and includes threads 127 helically turning around the wall 122 from both inner and outer sides of the inner coned tube 1005. The helical turning of the threads 127 can be either in clockwise or counterclockwise directions. The provision of the threads 127 on the wall of the inner coned tube provides a whirl effect for the air passing and exiting between the substrate 121 and the inner coned tube 1005, thereby enhancing the cooling of the photovoltaic elements 1006.

As shown in FIG. 11, the solar energy concentrator 12 placed as a crown on the top of the upper central tube 500 serves as a support for the motion sensor 420 and sun tracking sensor 450. According to this embodiment, the system for solar energy utilization includes a hemispherical support 400 on which the motion and sun tracking sensors 420 and 450 are mounted. In turn, the hemispherical support 400 is mounted on a hemisphere support tube 403 that can be connected to the crown, for example to the inner coned tube 1005. Electric cables 421 and 451 connecting the motion and sun tracking sensors 420 and 450 to the controller (135 in FIG. 1A) pass through a lumen of the hemisphere support tube 403, then through the upper central tube 500, further through the housing (94 in FIG. 9), and finally through the lower tube (618 in FIG. 1A).

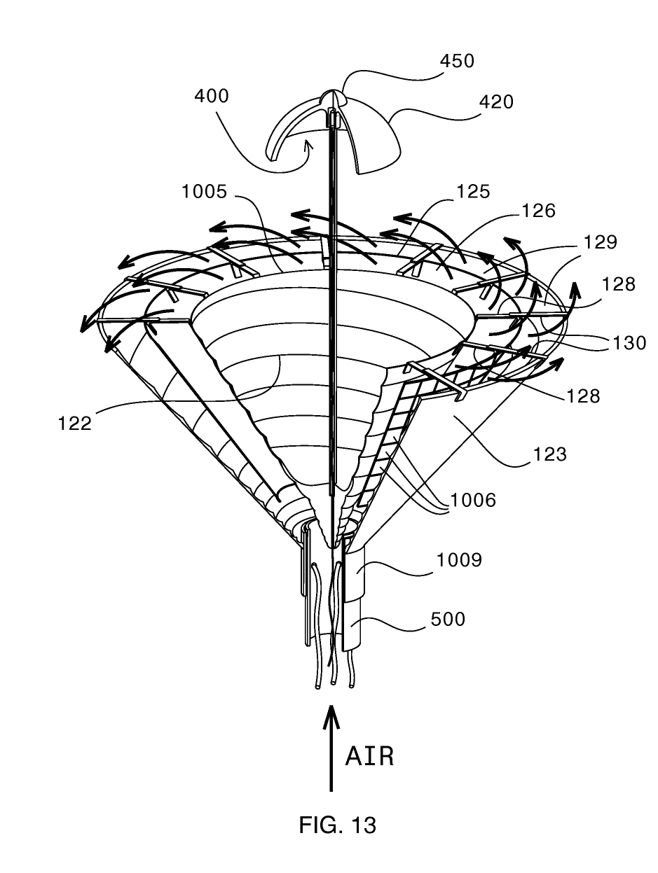

Reference is now made to FIG. 13, in which a perspective sliced cross-sectional view of the solar energy concentrator 12 is illustrated, according to another embodiment of the present invention. The solar energy concentrator 12 in FIG. 13 differs from the solar energy concentrator (12 in FIG. 11) in the fact that the cooling mechanism of the solar energy concentrator 12 further includes an outer coned tube 123 mounted outside of the substrate 121 on a sleeve 1008 mounted on the upper central tube 500.

The outer coned tube 123 is made from a material transparent to the light of sunbeams. Examples of the materials suitable for the outer coned tube 123 include, but are not limited to, a silicone glass that can be capable to withstand high temperatures, even exceeding 1000° C.

The outer coned tube 123 is axially symmetric and has a tapering angle of the conical part in the range of about 5 degrees to about 85 degrees with respect to an axis of the pole (14 in FIG. 1A). A diameter of a top of a conical mouth of the outer coned tube 123 is greater than the diameter of the conical mouth 125 of the substrate 121, thereby forming other circular slit 129 between the substrate 121 and the outer coned tube 123. The circular slit 129 provides another air channel for cooling the photovoltaic elements 1006 in addition to the air channel 126.

As shown in FIG. 13, the substrate 121 is not mounted on central tube 500, but rather mechanically connected to the outer coned tube 123 by means of connecting members 130. Similar to the connecting members 128 connecting the inner coned tube 1005 and the substrate 121, the connecting members 130 can include another rods or plates in the shape of square brackets attached to the walls of the outer coned tube 123 and the substrate 121. The connecting members 130 can, for example, be aggregated together with the connecting members 130, however, they can also be separated elements.

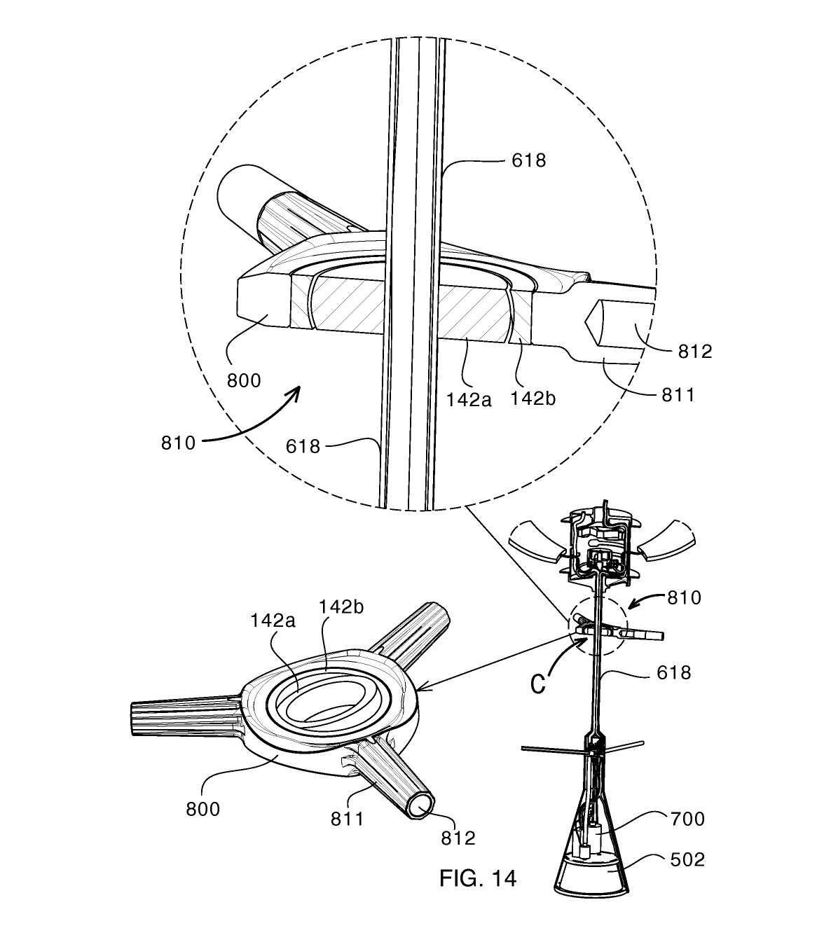

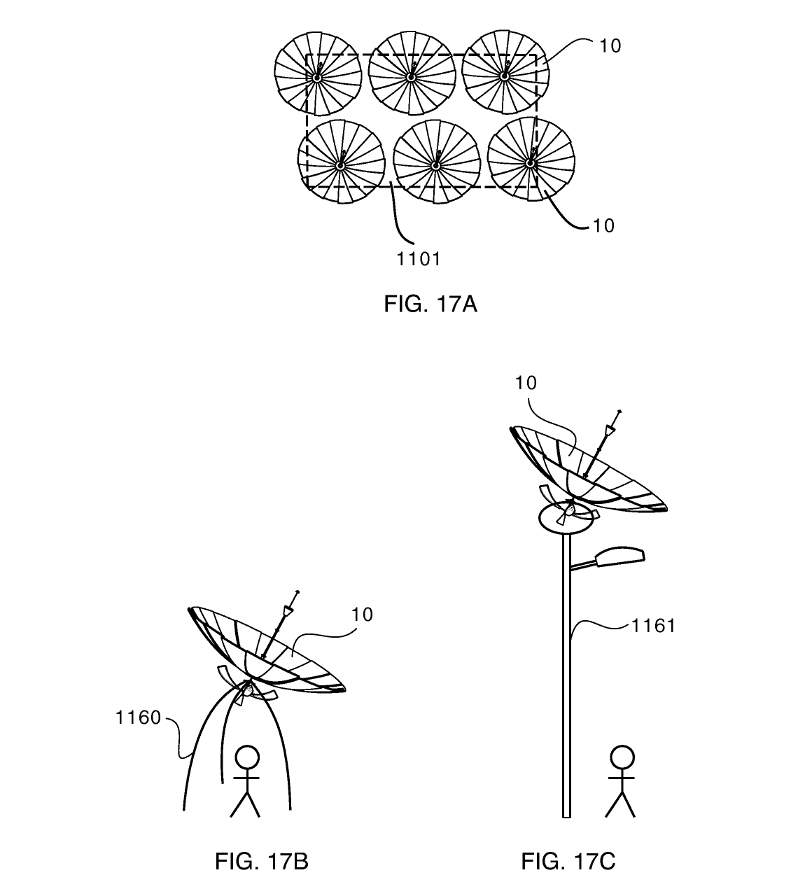

Reference is now made to FIG. 14, in which a perspective partial sliced cross-sectional view of the system 10 for solar energy utilization is illustrated with amplification of certain fragments, according to an embodiment of the present invention. The system 10 can be mounted on cables, mast, legs or other installation means, which are fixed and stationary as will be described hereinbelow with reference to FIGS. 17A through 19B, whereas the system 10 by itself can be turned by means of a pivot system 810 to orient the pole (14 in FIG. 1A) defining an axial direction of the system 10 towards the sun so that the flexible mirrors (200 in FIG. 1A) may receive maximum solar energy.

According to an embodiment, the pivot system 810 includes a bearing socket 800 that can be connected to any installation means (not shown), and a thrust bearing 142 arranged in the bearing socket 800. For connection to installation means the bearing socket 800 is integrated with sleeves 811 that have an opening 812 configured for inserting cables, legs or any other installation means therein.

The thrust bearing 142 includes a stationary outer race 142b attached to the inner surface of the bearing socket 800 and a movable inner race 142a supporting the system 10 at a pivot point located on the lower tube 618. Preferably, the pivot point is selected on the lower tube 618 at a center of rotation C of the system 10 so that the system 10 can easily rotate in altitudinal and azimuthal directions.

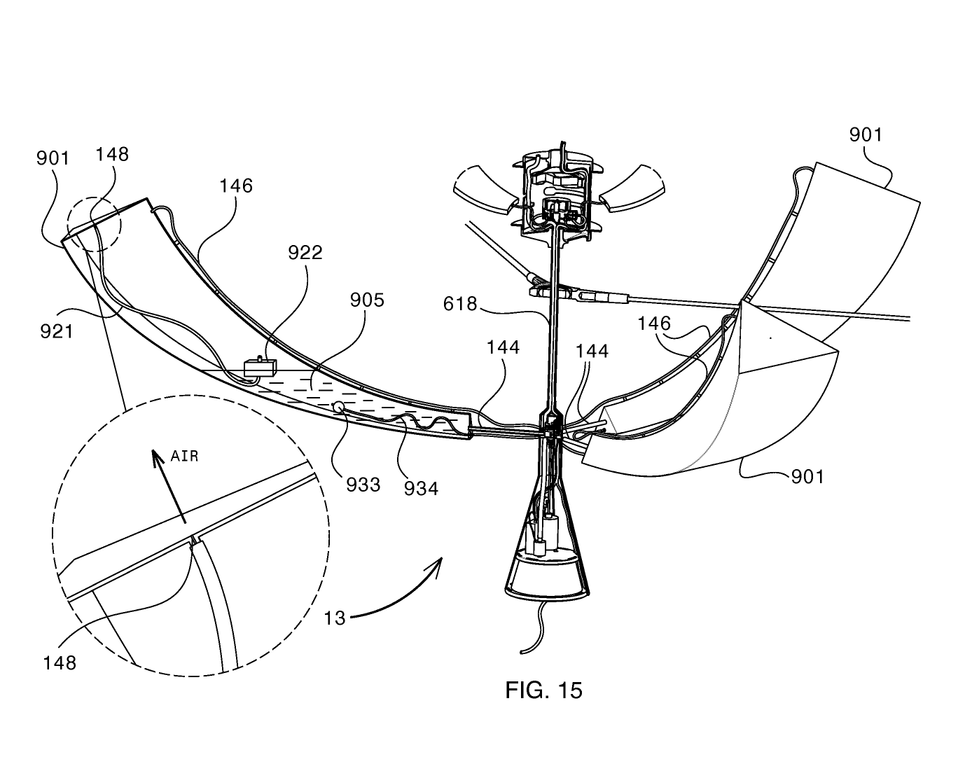

Reference is now made to FIGS. 15 and 16 together, in which a perspective sliced cross-sectional view of the solar tracking system 13 of the system (10 in FIG. 1A) for solar energy utilization is illustrated with amplification of certain fragments, according to an embodiment of the present invention. The solar tracking system 13 includes three fluid communicating balance tanks 901 extending from the main axis of the system in radial directions, with an angle of 120 degrees between each pair of the tank directions. The three balance tanks 901 contain liquid 905 that can be transferred between the tanks controllably via liquid communication tubes 146, thereby shifting the center of the mass of the system 10 and tilting the main axis of the system 10 in the desired direction, for example, towards the sun.

The liquid 905 can, for example, be placed in balance tanks 901 during installation of the system 10. After installation, it can circulate between the tanks 901 in close cycle. Under normal working conditions, the period for replacing or adding new liquid can be longer than one year. The fluid can, for example, be water or an antifreeze glycol mixture, which can operate at temperatures as low as −50° C.

In order to provide transferring the liquid 147 between the tanks 901, the solar tracking system 13 includes a second multi-way gas flow control valve (at least three-way) 152 connected to the multifunctional air controllable compressor 700 via a tube 143. The second multi-way gas flow control valve 152 is arranged under the center of rotation C of the system 10 and mounted in a housing 159 arranged at the bottom end of the lower tube 618.

The air from the compressor 700 can be controllably provided to any one tank selected from the tanks 901 via supporting air tubes 144 on which the tanks 901 are mounted at a proximal tank end with respect to the lower tube 618. The supporting air tubes 144 are made from a relatively strong material suitable to provide support and hold the tanks 901. The solar tracking system 13 also includes a second servo 150 arranged within the housing 159 and configured for setting the second multi-way air flow valve 152 to supply air from the compressor 700 to the selected tank 901 via the corresponding supporting air tube 144.

In operation, air is provided to the second multi-way gas flow control valve 152 from the compressor 700 via the tube 143. The valve 152 is associated with the bearings 155a and 155b which are connected to a rotation part of the valve 152 connected to the second servo 150 via a shaft 154. The second servo is electrically coupled to the controller 135 in FIG. 1D. The controller 135 is responsive, inter alia, to a sun tracking signal generated by the sun tracking sensor (450 in FIG. 1) and generates instruction signal to the controller connector switch 140 to activate the second servo 150 and turn the rotation part of the second multi-way valve 152 for connecting the compressor 700 to one of the tubes 144. As soon as the valve 152 connects the compressor 700 to the desired tube 144, the controller 135 generates a signal for activation of the compressor 700 in order to pass air in the corresponding tank 901.

The air passing in the tank increases air pressure in this tank. The increase of the pressure in the tank pushes the liquid out from this tank to the other tanks via the corresponding liquid communication tube 146, thereby shifting the center of the mass of the system 10 and tilting the main axis of the system 10 in the desired direction. After tilting and positioning the system in the desired direction, excessive air pressure in the tank is decreased. For this purpose the solar tracking system 13 includes a tank opening 148 arranged at a distant end of the tank for releasing the excessive air.

According to one embodiment, the tank 901 has such a curved shape in order to keep the opening 148 always above the level of the liquid. For example, the tank 901 can have a substantially banana-like shape with a tank opening 148 arranged at a distal end of the tank 901 with respect to the lower tube 618. Although a substantially triangular shape of the transverse cross-section the tank is shown in FIG. 15, generally, the tank 901 can have any other desired shape of the transverse cross-section, e.g., any polygonal, round or oval shape.

According to another embodiment, in order to keep the tank opening 148 always above the level of the liquid, the opening 148 can be connected to an opening pipe 921. Thus, one end of the pipe 921 is connected to the opening 148, whereas other opening pipe end of the opening pipe 921 is always kept above the level of the liquid by means of a float 922. It should be understood that for operation of the solar tracking system 13 is required that a flow rate the air passing in the tank 921 is greater than the air flow of the air that is released through the opening 148.

According to an embodiment, in order to keep the liquid communication passing below the level of the liquid and avoid transferring air between the tanks 901, the solar tracking system 13 may further include a passing liquid pipe 934 arranged in the tank 901. One end of the passing air pipe 934 is connected to the liquid communication tubes 146, whereas the other end of the passing liquid pipe 934 is always kept below the level of the liquid by using a sinker 933 attached to the other end of the passing liquid pipe 934. The sinker 933 has weight sufficient to keep the other end of the passing liquid pipe 934 immersed in the liquid 905 below the liquid level.

It should be also noted that the weight of liquid inside the tanks 901 is also used as a ballast weight to shift the center of gravity of the device down to the bottom of the system, thereby to increase the system's mechanical stability.

As described above, the air controllable compressor 700 is responsible, inter alia, for supplying and maintaining pressurized air inside the flexible inflatable frame (282 in FIG. 4) of the flexible mirrors. Moreover, the compressor 700 is used to provide compressed gas to the air tank 502 which provides compressed air for activation of the pneumatic piston 550 as described above with reference to FIG. 2. Thus, according to one embodiment of the present application the second multi-way gas flow control valve 152 can be a five-way gas flow control valve. In this case, three ways the five-way gas flow control valve can be used for controllable coupling the compressor 700 to the three balance tanks 901, and two other ways of the five-way gas flow control valve can be used for controllable coupling the compressor 700 to the pressure tank 502 via a pressure tank pipe 505 connected to the pressure tank 502 through a one way valve 506, and to the first multi-way valve (91 in FIG. 9) via a pipe 145 for filling the flexible mirrors 200, correspondingly.

The housing 159 arranged at the bottom end of the lower tube 618 and connected thereto can, inter alia, contain the compressor 700, the controller 135, the pressure tank 502 and the one-way valve 506. The housing 159 can be constructed from one or several pieces made of a material suitable to withstand harsh atmospheric conditions to protect the electronic and other parts from damage.

Reference is now made to FIGS. 17A-17C, which schematically illustrate the possibilities of installation of the system 10, in accordance with several embodiments of the present invention. The system 10 may have relatively low weight when compared to conventional systems for utilization of solar energy. This feature enables new possible utilizations and installations, which were impossible hitherto with conventional solar systems.

FIG. 17A illustrates an example of installation of the system 10 on a roof area 1101 which is overlapped by the systems 10, thus enabling to utilize more area for solar radiation than the roof area 1101.

FIG. 17B illustrates an example of installation of the system 10 on legs 1160. Such an installation can, for example, be used in a garden amongst trees, in a livestock farm and even in children's playgrounds, etc. without any need for barriers or fences, because no electrical or danger from heat is created. The length of legs 1160 can be adjusted to be fitted to the place of installation. When required, the system 10 can be elevated such that enough space would remain for the passage of subjects under the system 10. The system 10 can be lightweight and has relatively small dimensions when collapsed to the closed state, thus making it portable, and allowing easy transportation and reposition. The inflatable mirrors can be detached, deflated and stored for transportation. The system weight can be less than 0.5 kg/m² solar energy-receiving mirrors 200.

Owing to the use of the movement sensor (420 in FIGS. 1A and 1D) the “flower-type” system 10 can automatically close when people or livestock are approach it.

It should be understood that proper placement of the system may provide shade that is useful for animals and plant vegetation. This provision allows avoiding annexation of public or private land for solar system installation, and therefore does not require uprooting life species from any given location.

FIG. 17C illustrates an example of installation of the system 10 on public lampposts 1161.

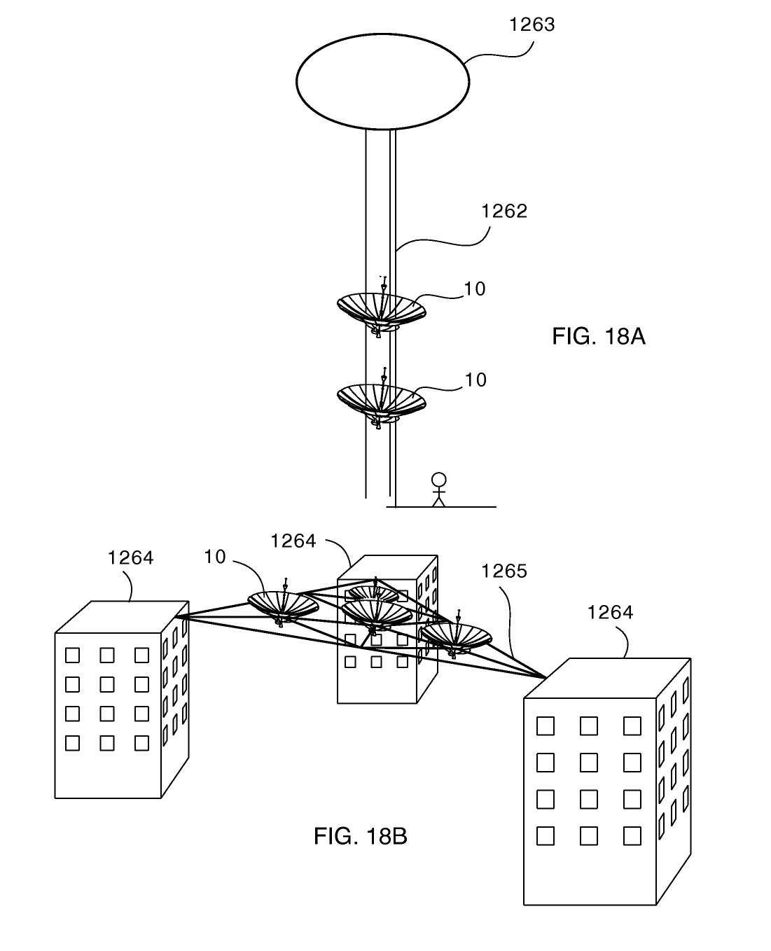

Reference is now made to FIGS. 18A and 18B, which illustrate simplified schematic illustrations of installation of the systems 10 on various cable systems for vertical and horizontal installations, in accordance with an embodiment of the present invention. As shown in FIG. 18A, the systems 10 are positioned on vertical cables 1262 which are held up by balloon 1263. In this way, vertical power stations may be built in such places such as skyscrapers, factories, drilling platforms and other such locations, where the demand for electric consumption is rather high. FIG. 18B illustrates an example of horizontal installation of the systems 10 on a rope net 1265 between houses 1264.

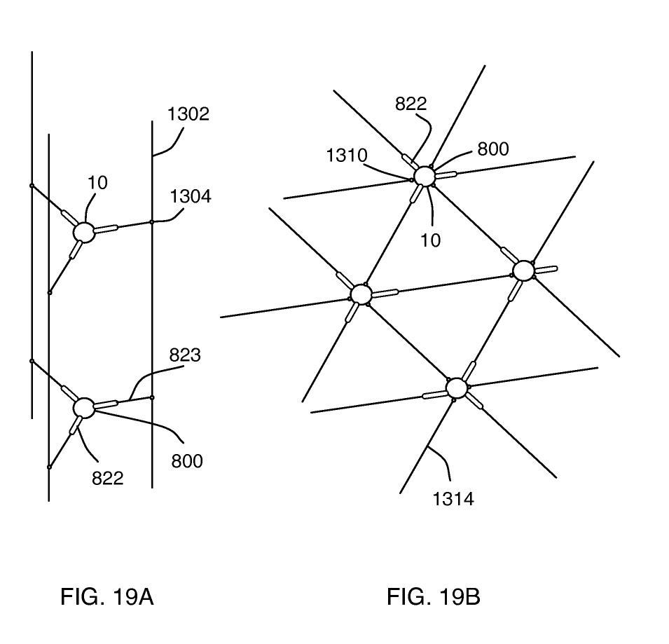

Reference is now made to FIGS. 19A and 19B, which are simplified schematic illustrations of a vertical configuration of cables 1302 and a horizontal configuration of cables 823 and 1314, correspondingly, on which a plurality of the systems (10 in FIG. 1A) are mounted, in accordance with various embodiments of the present invention. FIG. 19A shows a more detailed view for the supporting element of the three cables (1262 in FIG. 18A). This kind of installation provides full stabilization and avoids rotation of the system 10 when the wind changes its direction.

Referring to FIGS. 14 and 19A together, the system 10 is connected to the cables 823 through the sleeves 811 of the bearing socket 800. The cables 823 can be fixed in the openings 812 of the sleeves 811 at one end of the cables and to the vertical cable 1302.

Referring to FIGS. 14 and 19BA together, a more detailed view for system installation on the honeycomb shape net of the cables 1314 is illustrated, in accordance with an embodiment of the present invention. The systems 10 are connected through the sleeves 811 of the bearing socket 800 to horizontal cables 1314.

It should be understood that the system of the present invention can be mechanically connected to many other cable configurations, mutatis mutandis, either vertically or horizontally, thus forming a line or a net.

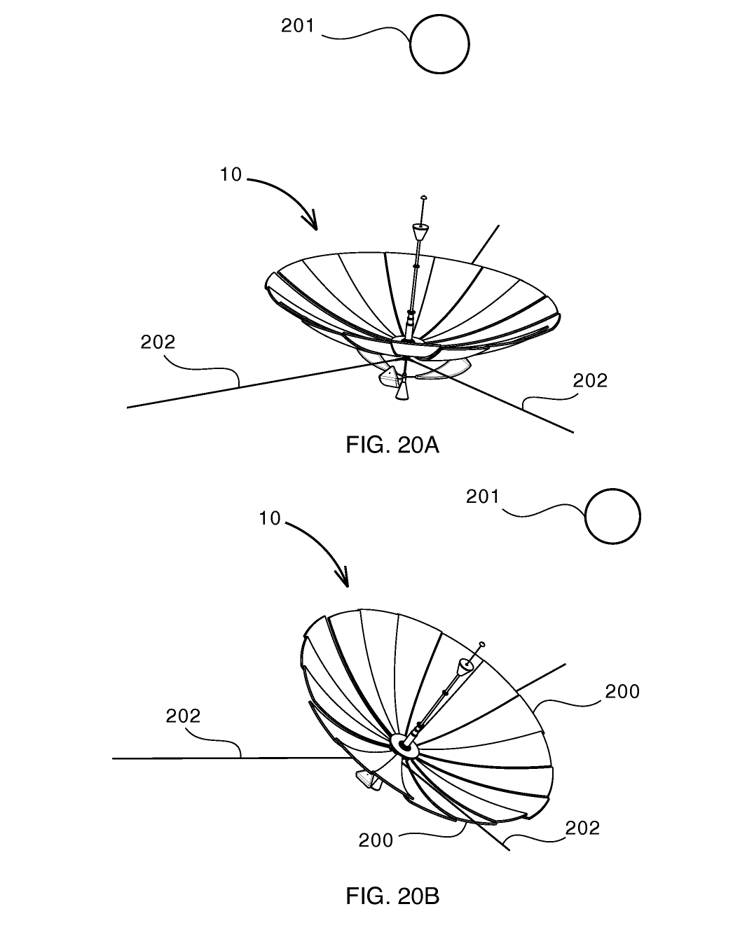

Referring to FIGS. 20A and 20B, during positioning, altitude directions of the system 10 can be varied at a broad range of tiling angles. When required for tracking the sun 201, installation cables 202 can be placed between the flexible mirrors 200, due to the petal-like shape of the solar receiver.

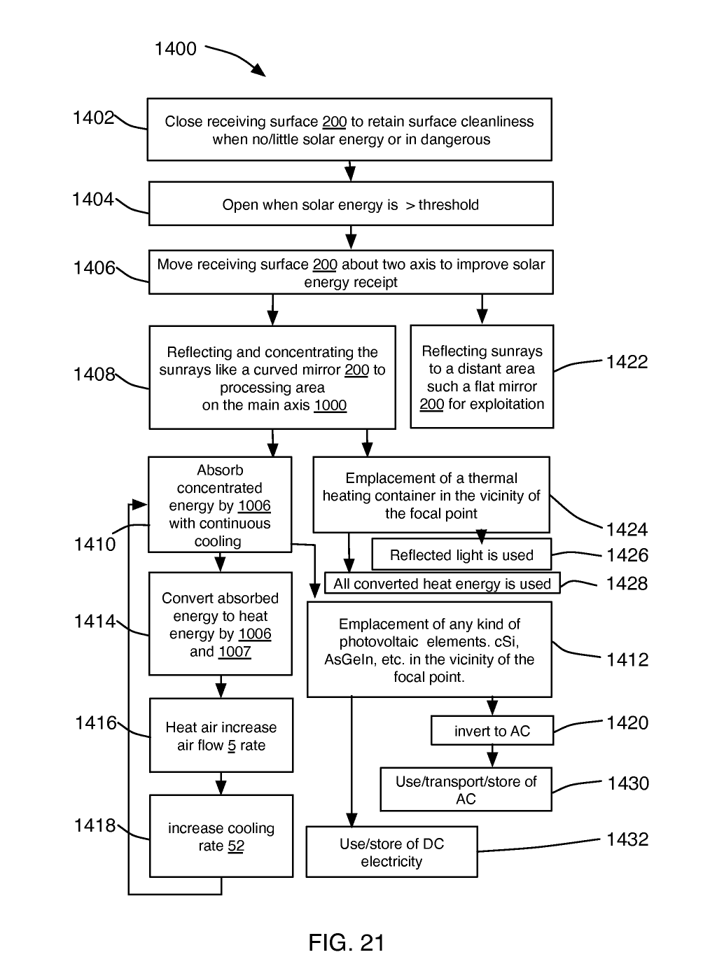

Referring to FIG. 21, a flow chart illustrating a method 1400 for converting solar energy into electric energy, into heat energy or reflect light with the system of FIG. 1A is shown, in accordance with an embodiment of the present invention. Utilizations of the device include, but are not limited to, the following;

1) Reflecting and concentrating sun-beams like a curved mirror to the processing area, its center being on the main axis.

2) Reflecting sunrays to a distant area such as a flat mirror for exploitation. For example, in a solar tower based heat storage/electricity production facility, or in a solar tower based high temperature furnace etc.

3) Emplacement of a thermal heating container in the vicinity of the focal point.

4) Emplacement of any type of photovoltaic (PV) element means: using yny type of elements including cSi, AsGeIn, carbon, etc. in the vicinity of the focal point.

The upper central tube 500 creates a pedestal for the solar receiver, which could be the crown 1000 already described in detail, or any other kind of heat or concentrated light processing machine, motor, electric generator, heat exchanger etc. These kinds of energy processing devices can use passive air cooling without motors or turbines. These kinds of energy processing devices can use also active air cooling when a motor with a turbine is utilized to generate air flow, and could be placed inside the upper central tube 500. The solar energy concentrator 12 (or other energy processing devices) could be totally removed in the event that the system device 10 is used only for mirroring sunlight.

In a closing receiving surface, step 1402 closes the receiving surface of the flower of mirrors 200 to retain surface cleanliness when no/little solar energy is present, or any danger exists.

In opening step 1404, the flower of mirrors 200 is opened when the solar energy step is greater than a predefined threshold.

In a move receiving surface step 1406, the receiving surface of the mirrors 200 is rotated about two axes to improve solar energy receipt to a maximum possible amount of energy.

In a reflecting and concentrating step 1408, the received energy is reflected and concentrated from the receiving surface to a concentrating area on the crown 1000.

In an absorbing concentrated energy step 1410, the concentrated energy is absorbed with continuous cooling.

In a conversion step 1412, the absorbed energy is converted into DC energy.

In a second conversion step 1414, the absorbed energy is converted into heat energy.

In a heating air step 1416, the air is heated to increase the air flow rate 5.

In an increasing cooling rate step 1418, the cooling rate is increased.

In an inverting to AC, step 1420, the DC energy from step 1412 is inverted into AC.

In a use/transporting step 1430, the AC energy produced in step 1420 is used and/or transported and/or stored.

In a use or store DC energy step 1432, DC electricity is used or stored.

In an absorbing all concentrated energy step 1424, all concentrated energy from step 1408 is absorbed.

In a use all converted heat energy step 1428, all converted heat energy is used.

In a reflecting step 1422, received light is reflected without concentrating.

In a use reflected light step 1426, the reflected light is used.

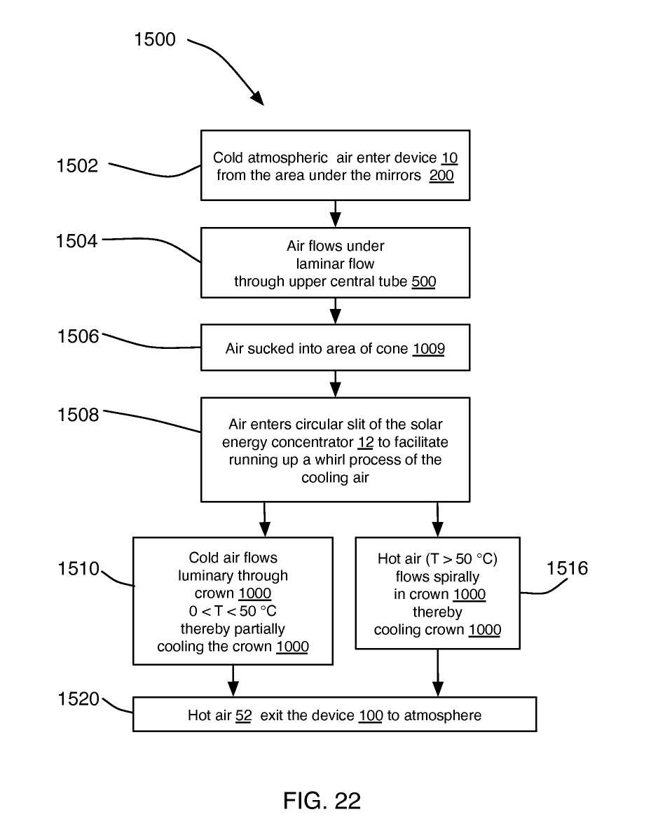

Reference is now made to FIG. 22, which is a simplified flowchart 1500 of a method for cooling the solar energy concentrator (crown) 12 of the system of FIG. 1A, in accordance with an embodiment of the present invention.

In a cold air entry step 1502, cold air enters device 10 from the area under the mirrors 200.

In an air flowing step 1504, air flows under laminar flow through the central tube 500.

In an air sucking step 1506, air is sucked into the system.

In air inletting spiral cone step 1508, air enters the circular slit (126 in FIG. 12) (i.e., spiral cone) of the solar energy concentrator 12 to facilitate running up a whirl process of the cooling air.

In a cold air flowing luminary step 1510, cold air flows through the crown of the solar energy concentrator 12 at a temperature range of −50° C.>T>50° C. thereby partially cooling the crown.

In a hot air flowing spirally step 1516, hot air (at a temperate T greater than 50° C.) flows spirally in the solar energy concentrator 12 (crown), thereby cooling the crown.

In an air exiting step 1520, air exits system 10 to the atmosphere.

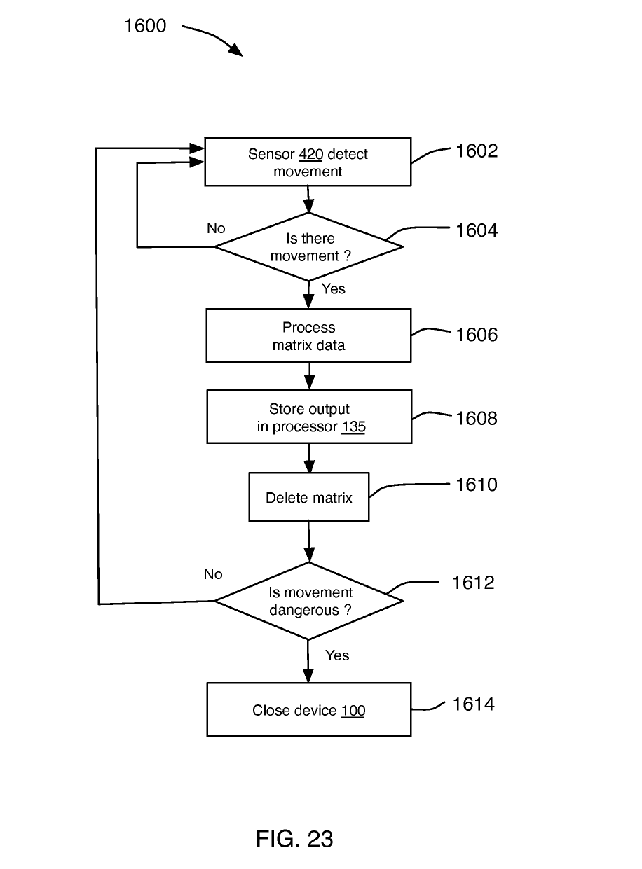

Reference is now made to FIG. 23, which is a simplified flowchart 1600 of a method for active protection of the system (10 in FIG. 1A) from approaching subjects that can damage the system, in accordance with an embodiment of the present invention.

In sensor detecting movement step 1602, the movement sensor (420 in FIG. 1D) detects external movements.

Thereafter, in a movement checking step 1604, the sensor checks to see if there is movement. In a processing step 1606, the processor processes matrix data.

In a storing output step 1608, the processor stores the output from step 1606.

In a deleting step 1610, the matrix data is deleted.

In checking danger of movement step 1612, it is checked to see if the movement presents any danger.

If so, the system 10 is closed (collapsed) in a closing device step 1614.

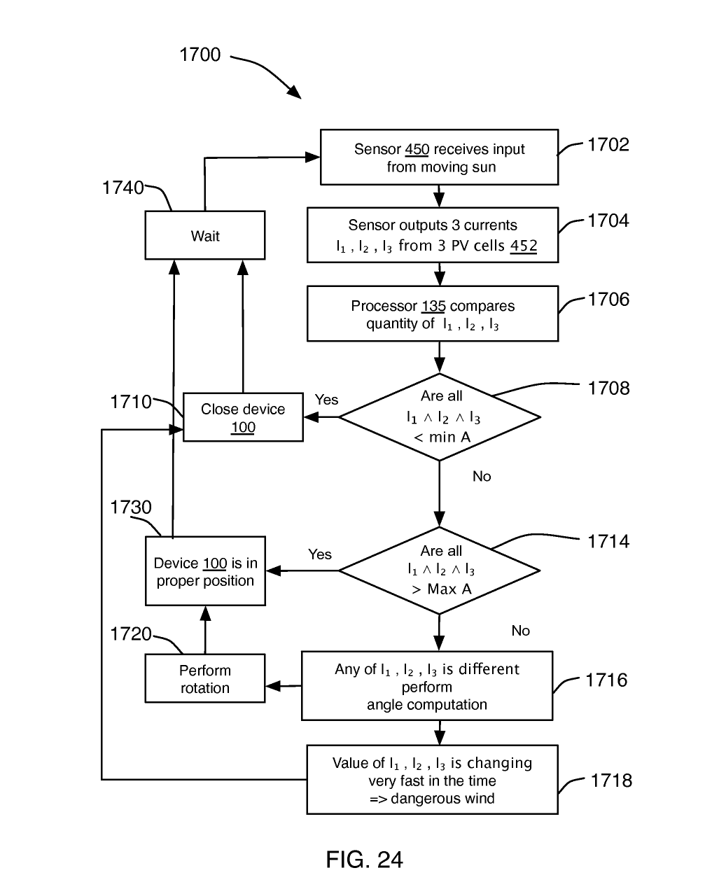

Reference is now made to FIG. 24, which is a simplified flowchart 1700 of a method for tracking the sun's movement, in accordance with an embodiment of the present invention.

In a sensing step 1702, the sun tracking sensor (450 in FIG. 1D) receives inputs relating to the sun's movements.

In a sensor outputting step 1704, the sun tracking sensor 450 outputs three separate currents I1, I2 and I3 from three photovoltaic cells (1006 in FIGS. 11 and 12).

In a processing step 1706, the controller 135 compares quantity of I1, I2 and I3.

In a first checking step 1708, the processor checks to see if electric currents I1, I2 and I3 are all less than a threshold value.

In a closing device, step 1710, the solar receiver 11 is closed.

In a second current checking step 1714, the values of I1, I2 and I3 are compared by the controller 135 in dependency of mutual values. If the values are mostly same amount then the next step is performed.

In a proper position step 1730, the system 10 is in a proper position and continues to wait for step 1740.

In a second current checking step 1714, it is ascertained if any of I1, I2 and I3 are different values than others in a predefined range.

In an angle computation step 1716, an angle computation is performed by processor.

In an time compare step 1718 the I1, I2 and I3 values are compared with their previous values and if they changed too fast in the time, device is in strong wind

and active closing is processed.

In a perform rotation step 1720, system 10 is rotated by the solar tracking system 13 as described above with reference to FIGS. 15 and 16.

In a waiting step 1740, the processor waits time t.

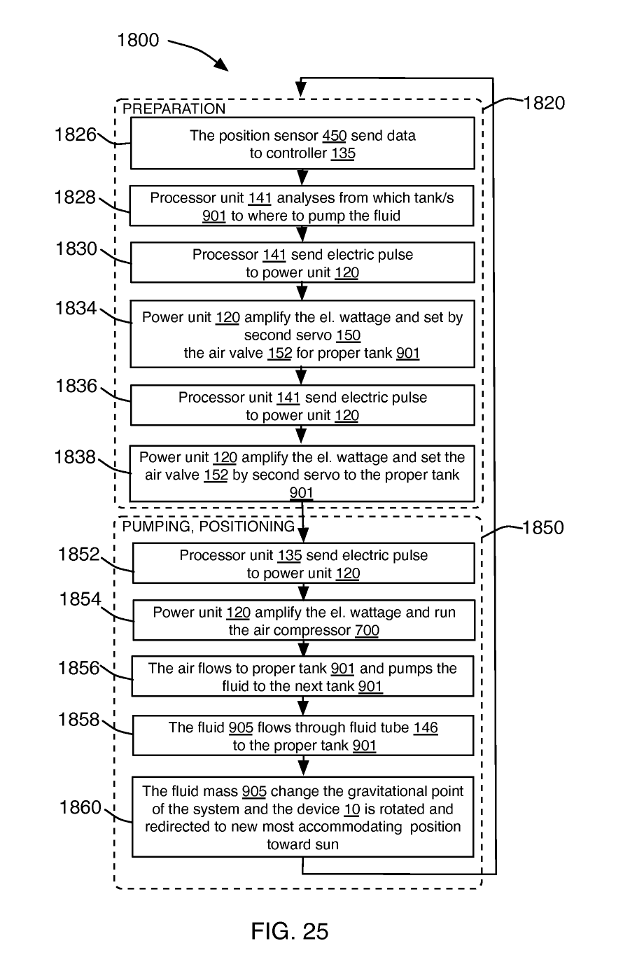

Reference is now made to FIG. 25, which is a simplified flow chart 1800 of a method for positioning the system (10 in FIG. 1A), in accordance with an embodiment of the present invention. The entire method is created by two main phases. The first main phase includes a preparation step 1820 and includes computation in the processor and setting valves. No movements occur with the system 10 during this phase. The second main phase includes pumping air in the tanks 901, and positioning 1850 the system, which are physical processes of transferring liquids between the tanks, and tilting the system 10.

Phase I—Preparation 1820.

In the position data send, step 1826, the position sensor 450 sends data to the controller 135.

In a processor unit analyzing step 1828, the controller 135 analyses from which tank 901 and to which other tank 901 to transfer the liquid.

In processor sending step 1830, the processor 141 sends electric pulse through controller connector switch 135 to power unit 120.

In power amplifying step 1834, the controller connector switch 135 prepares the electric voltage and sets (by using the second servo 150) the air valve 152 to the proper tank 901 to increase the air pressure in this tank, thereby the proper tank is activated for transferring liquid to other tanks.

In pulse sending step 1836, processor 141 sends an electric pulse to power unit 120.

In power unit amplify step 1838, the controller connector switch 135 prepares the electric voltage and sets the air valve 152 by the second servo 150 to the proper tank 901.

Phase I—Pumping and Positioning 1850.

In processor send electric pulse step 1852, processor unit 135 sends an electric pulse to the power unit 120.

In power amplify, step 1854, power unit amplifies the electric wattage and run the air compressor 700.

In the air flows, step 1856, the air flows in the selected tank 901 and pushes the liquid to the next tanks 901.

In the fluid flows step 1858, the fluid 905 flows through fluid tube 146 from the selected tank flows to another proper tank 901.

In the fluid mass step 1860, the liquid mass 905 changes the gravitational center of the system 10, and the system is rotated and redirected to a new, most accommodating position.

As such, those skilled in the art to which the present invention pertains, can appreciate that while the present invention has been described in terms of preferred embodiments, the concept upon which this disclosure is based may readily be utilized as a basis for the designing of other structures and processes for carrying out the several purposes of the present invention.

The present invention is not limited to generation of electricity, thus the system for solar energy utilization can be also used for heating objects located in the crown area of the solar concentrator.

Also, it is to be understood that the phraseology and terminology employed herein are for the purpose of description and should not be regarded as limiting.

In the method claims that follow, alphabetic characters used to designate claim steps are provided for convenience only and do not imply any particular order of performing the steps.

It is important, therefore, that the scope of the invention is not construed as being limited by the illustrative embodiments set forth herein. Other variations are possible within the scope of the present invention as defined in the appended claims and their equivalents.

1. A solar energy utilization system (10) comprising:
a solar receiver (11) configured for receiving solar energy from the sun and concentrating the received solar energy at a predetermined spot area, the solar receiver comprising a plurality of flexible mirrors (200) independent of each other and radially arranged around a main axis of the system, said plurality of flexible mirrors (200) being configured to be either deployed for operation or collapsed;
a solar energy concentrator (12) mounted on a pole (14) extending from the solar receiver (11) along the main axis of the system, the solar energy concentrator (12) being located at the predetermined spot area in which the solar energy reflected from said plurality of flexible mirrors (200) is concentrated, and configured for converting the concentrated reflected energy into electric energy;
a solar tracking system (13) configured for sensing position of the sun in the sky and tilting the system (10) for directing the solar receiver (11) towards the sun to receive and reflect maximum sunlight onto the predetermined spot area.

2. The solar energy utilization system of claim 1, wherein the solar receiver (11) comprises a hub (300) including a plurality of disks arranged along the main axis of the system and suitable for holding the flexible mirrors (200).

3. The solar energy utilization system of claim 2, wherein the hub (300) comprises an upper bedplate cover disk (315a), a lower bedplate cover disk (315b) and a plurality of mirror holding disks (316) sandwiched between the upper bedplate cover disk (315a) and the lower bedplate cover disk (315b), the mirror holding disks (316) being configured for securing and holding the flexible mirrors (200).

4. The solar energy utilization system of claim 3, wherein the solar receiver (11) comprises three mirror holding disks (316), and eighteen flexible mirrors (200) arranged in three layers formed by the three holding disks (316), each mirror holding disk (316) holding six flexible mirrors (200).

5. The solar energy utilization system of claim 3, wherein the solar receiver (11) comprises a leaf locking mechanism (318) configured for holding the flexible mirrors (200) in the mirror holding disks (316), the mirror holding disks (316) comprise a “female” part (318a) of the leaf locking mechanism (318) securing the flexible mirrors (200) in the radial positions around the main axis of the system, and each flexible mirror (200) includes a “male” part (318b) of the locking mechanism (318) mating the “female” part (318a) arranged in the corresponding holding disks (316).

6. The solar energy utilization system of claim 5, wherein each female part (318a) comprises a corresponding slit (317) arranged in the holding disk (316) an inner surface of the slits (317) including at least one slit irregularity (319a) in a tooth shape, and each flexible mirror (200) comprises at least one corresponding leaf irregularity (319b) having a shape suitable to mate with said at least one slit irregularity (319a).

7. The solar energy utilization system of claim 2, wherein the solar receiver (11) further comprises a pneumatic mirror folding mechanism (16) comprising:
a movable ring (520) mounted on the pole (14) and capable to slide along the main axis of the system;
folding strings (261) attached to the flexible mirrors (200); and
a pneumatic piston (550) mounted on the top of the hub (300) and configured to lift the movable ring (520);
whereby the flexible mirrors (200) are folded in the radial direction toward the pole (14) by lifting the movable ring (520) up to pull the folding strings (261).

8. The solar energy utilization system of claim 7, wherein the solar receiver (11) comprises an air tank (502) coupled to the pneumatic piston (550) via an air line (501) including a controllable electromagnetic air valve (503); whereby the pneumatic piston (550) is activated by pressurized air passing from the air tank (502) after opening the controllable electromagnetic air valve (503).

9. The solar energy utilization system of claim 7, wherein the pneumatic piston (550) comprises a plurality of concentric tubes (551) telescopically arranged along the main axis.

10. The solar energy utilization system of claim 8, wherein the system (10) further comprises an air controllable compressor (700) coupled to the air tank (502) for filling thereof with compressed air.

11. The solar energy utilization system of claim 10, wherein the air controllable compressor (700) is coupled to the air tank (502) via a multi-way gas flow control valve (152).

12. The solar energy utilization system of claim 7, wherein the folding mechanism (16) includes an electromagnetic lock device (580) mounted on the pole (14) and configured to lock the movable ring (520), thereby holding the flexible mirrors (200) in the folded state.

13. The solar energy utilization system of claim 12, wherein the lock device (580) includes an electromagnetic trigger (584) configured for unlocking the lock device (580) and releasing the movable ring (520).

14. The solar energy utilization system of claim 3, wherein each flexible mirror (200) comprises an inflatable supporting member (250) configured for connecting to the mirror holding disks (316), and a working member (220) that is mounted on the inflatable supporting member (250).

15. The solar energy utilization system of claim 14, wherein the inflatable support element (250) comprises a flexible inflatable frame (282) having a ladder shape and including inflatable radial beams (28a and 28b) fortified by a plurality of inflatable cross ribs (290).

16. The solar energy utilization system of claim 14, wherein the inflatable supporting member (250) of the flexible mirrors (200) comprises a leaf locking mechanism (318a) for securing an end part (291) of the inflatable supporting member (250) in the holding disks (316).

17. The solar energy utilization system of claim 14, wherein the proximal end (291) of the inflatable supporting member (250) includes a nipple air valve (288) configured for inflation of flexible inflatable frame (282).

18. The solar energy utilization system of claim 14, wherein the system (10) further comprises an air controllable compressor (700) coupled to the inflatable supporting member (250) for filling thereof.

19. The solar energy utilization system of claim 14, wherein the inflatable supporting member (250) is enveloped by a fiber mesh (286) for fortifying the supporting member (250).

20. The solar energy utilization system of claim 19, wherein the inflatable supporting member (250) is covered by radial shaping strings (295) crossing the inflatable supporting member (250) in radial directions and by circumferential shaping strings (296) crossing the inflatable supporting member (250) in the circumferential direction, which is perpendicular to the radial directions.

21. The solar energy utilization system of claim 20, wherein the shaping strings (295) are interlaced with the fiber mesh (286) along the radial direction, whereas the shaping strings (296) are interlaced with the fiber mesh (286) along the ribs (290).

22. The solar energy utilization system of claim 21, wherein shaping strings (295 and 296) include SILON™ wire.

23. The solar energy utilization system of claim 19, wherein the inflatable supporting member (250) further includes at least one folding string (261) attached to a distal end (281) of the inflatable supporting member (250).

24. The solar energy utilization system of claim 23, wherein the inflatable supporting member (250) comprises guide tubes (287), which are attached to the fiber mesh (286) at the foldable cross ribs (290) and configured to provided passage of the folding strings (261) unrestrictedly therethrough.

25. The solar energy utilization system of claim 15, wherein the foldable cross ribs (290) of the inflatable supporting member (250) include a weakened longitudinal cross-section (285) around which the foldable cross ribs (290) kink or buckle to deform and move the radial beams (28a) and (28b) towards each other.

26. The solar energy utilization system of claim 15, wherein the working member (220) includes a covering mesh (229) attached to the top of the inflatable supporting member (250).

27. The solar energy utilization system of claim 26, wherein the working member (220) includes a plurality of flexible reflective plates (222) attached to the covering mesh (229).

28. The solar energy utilization system of claim 27, wherein the flexible reflective plates (222) are regularly arranged and overlap with each other, thereby filling completely the top surface of the working member (220).

29. The solar energy utilization system of claim 27, wherein the flexible reflective plates (222) are sparsely dispersed within the top surface of the working member (220).

30. The solar energy utilization system of claim 27, wherein the flexible reflective plates (222) are arranged in a fish scale fashion.

31. The solar energy utilization system of claim 27, wherein the flexible reflective plates (222) are deflectable from the surface of the working member (220), thereby forming holes (221) between the plates (222) to enable an air stream to flow through these holes, and returning the flexible reflective plates (222) to their operating position during the absence of the air stream.

32. The solar energy utilization system of claim 27, wherein a space is provided between flexible mirrors (200) enabling an air stream to flow through them.

33. The solar energy utilization system of claim 15, wherein the solar receiver (11) includes an air checking and filling mechanism (90) configured for controllable checking pressure in the flexible inflatable frame (282) of the flexible mirrors (200), and for filling the flexible mirrors (200) with air when required, the air checking and filling mechanism (90) comprises a first multi-way air flow valve (91) configured to supply air to the flexible inflatable frame (282).

34. The solar energy utilization system of claim 33, wherein the first multi-way air valve (91) is coupled to the air controllable compressor (700) via an air pipe 96 connected to the compressor (700) via a second multi-way air valve (152).

35. The solar energy utilization system of claim 33, wherein the solar receiver (11) further includes a first servo (180) configured for setting the first multi-way valve (91) to supply pressurized air from the compressor (700) to a selected flexible mirror (200).

36. The solar energy utilization system of claim 1, wherein the solar energy concentrator (12) comprises a substrate (121) having a funnel shape with a wide conical substrate mouth (122) with expansion towards a top end of the system, and a narrow stem including a sleeve connector (1004) mounted on the pole (14).

37. The solar energy utilization system of claim 36, wherein the substrate (121) is axially symmetric and has a tapering angle of the conical part in the range of about 5 degrees to about 85 degrees with respect to an axis of the pole (14).

38. The solar energy utilization system of claim 37, wherein the substrate (121) has an outer surface (1007) configured for mounting solar photovoltaic (PV) elements (1006) thereon to generate electricity.

39. The solar energy utilization system of claim 38, wherein the solar photovoltaic (PV) elements (1006) are photovoltaic elements including at least one material selected from arsenic-germanium-indium (AsGeIn), crystalline silicone (c-Si) and carbon.

40. The solar energy utilization system of claim 1, wherein the solar energy concentrator (12) comprises an air-based cooling mechanism.

41. The solar energy utilization system of claim 37, wherein the solar energy concentrator (12) comprises an air-based cooling mechanism, the cooling mechanism comprises an inner coned tube (1005) mounted inside of the substrate (121), the inner coned tube (124) being axially symmetric and having a diameter of a top of a conical mouth of the inner coned tube (1005) less than the diameter of the conical mouth (125) of the substrate (121) to form a circular slit (126) between the substrate (121) and the inner coned tube (1005), thereby an air channel is formed for passing air to cool the photovoltaic elements (1006), the air channel enables the air to pass from the area below the solar receive (11), through the pole, and finally through the slit (126).

42. The solar energy utilization system of claim 41, wherein the cooling mechanism further comprises a fan (136) located along said air channel and configured to facilitate air flow in the air channel.

43. The solar energy utilization system of claim 41, wherein the inner coned tube (1005) is mechanically connected to the substrate (121) by means of connecting members (128).

44. The solar energy utilization system of claim 43, wherein the connecting members are selected from rods and plates in the shape of square brackets radially extending across the circular slit (126) and attached to the walls of the inner coned tube (1005) and the substrate (121).

45. The solar energy utilization system of claim 41, wherein a wall (122) of the inner coned tube (1005) is wavy in shape and includes threads (127) helically turning around the wall (122) from both inner and outer sides of the inner coned tube (1005), thereby to provide a whirl effect for the air passing and exiting between the substrate (121) and the inner coned tube (1005) to enhance cooling of the photovoltaic elements (1006).

46. The solar energy utilization system of claim 41, wherein the cooling mechanism further comprises an outer coned tube (123) mounted outside of the substrate (121) on a sleeve (1008) mounted on the pole (14) and is made from a material transparent to the light of sun-beams, the outer coned tube (123) being axially symmetric and having a diameter of a top of a conical mouth of the outer coned tube (123) greater than the diameter of the conical mouth (125) of the substrate (121), thereby forming another circular slit (129) between the substrate (121) and the outer coned tube (123), whereby said another circular slit (129) provides another air channel for cooling the photovoltaic elements (1006) in addition to the air channel (126).

47. The solar energy utilization system of claim 1, further comprising a pivot system (810) for orienting the main axis of the system (10) towards the sun, the pivot system (810) comprising a bearing socket (800) integrated with sleeves (811) having an opening (812) configured for inserting installation members, and a thrust bearing (142) arranged in the bearing socket (800), the thrust bearing (142) including a stationary outer race (142b) attached to the inner surface of the bearing socket (800) and a movable inner race (142a) supporting the system (10) at a pivot point located on the pole (14) at a center of rotation (C) of the system (10).

48. The solar energy utilization system of claim 1, wherein the solar tracking system (13) includes three fluid communicating balance tanks (901) extending from the main axis of the system in radial directions with an angle of 120 degrees between each pair of the tank directions; said three balance tanks (901) contain liquid (905) being transferred between the tanks controllably via liquid communication tubes (146), thereby shifting the center of the mass of the system (10) and tilting the main axis of the system (10) in a desired direction.

49. The solar energy utilization system of claim 48, wherein the solar tracking system (13) includes a second multi-way gas flow control valve (152) coupled to an air compressor (700) and configured for controllably providing air to one tank selected from the tanks (901) to increase pressure in the selected tank and thereby to push the liquid out from the selected tank into the other tanks (901); and a second servo (150) configured for setting the second multi-way air flow valve (152) to supply air from the air compressor (70) to a desired tank (901).

50. The solar energy utilization system of claim 49, wherein each tanks (901) of the solar tracking system (13) includes a tank opening (148) arranged at a distant end of the tank (901) for releasing excessive air.

51. The solar energy utilization system of claim 48, wherein the solar tracking system (13) includes an opening pipe (921) arranged in the tank (901) and having one pipe end being connected to the tank opening (148) and other pipe end being always kept above the level of the liquid (905); and a float (902) configured to float on the liquid (905) and support said other pipe end of the tank opening (148) above the level of the liquid (905).

52. The solar energy utilization system of claim 48, wherein the solar tracking system (13) includes a passing liquid pipe (934) arranged in each tank (901), the passing liquid pipe (934) having one pipe end connected to the liquid communication tube (146) and other pipe end being always kept below the level of the liquid (905); and a sinker (933) attached to the other pipe end configured to keep the other pipe end immersed in the liquid (905).

53. The solar energy utilization system of claim 1, comprising an air compressor (700) configured for providing pressurized gas for activation of folding the mirrors and tracking the sun; the solar receiver (11) comprises an electromagnetic trigger (581) configured for unlocking the flexible mirrors (200) when the mirrors are in a folded state; an electromagnetic valve (503) configured for providing compressed air for folding the flexible mirrors (200), a first servo (180) associated with a first multi-way valve (91) and configured for setting the first multi-way valve (91) to supply pressurized air from the compressor (700) to a selected flexible mirror (200) for filling the selected mirror with air when required, a second servo (150) associated with a second multi-way air flow valve (152) and configured for setting the second multi-way air flow valve (152) to supply air from the compressor (700) to the solar tracking system (13), and a fan (136) configured for providing air for cooling the solar tracking system (13).

54. The solar energy utilization system of claim 53, further comprising:
a control system (15) configured for control of the operation of the system (10),
the control system comprising:
a power supply unit (120) configured to provide electric power required for operation of electric and electronic modules of the system;
at least one sensor selected from the group consisting of:
a output voltage sensor (157) configured for measuring the output voltage generated by the system (10);
a motion sensor (420) configured for detecting moving objects in the vicinity of the system that might be potentially hazardous for the system (10);
a sun tracking sensor (450) configured for recognizing the location of the sun;
a mirror pressure sensor (185) configured for measuring the air pressure that is required for deploying the solar receiver (11);
a power voltage sensor (158) configured for measuring the power supply voltage provided by the power supply unit (120);
an output voltage sensor (157) configured for measuring output voltage generated by the solar energy concentrator (11)
a controller (135) coupled to at least one of the sensors and configured for analyzing the received sensor data and generating control signals to the controller connector switch (140) to controllably provide electric power supply voltages from a power supply unit (120) to at least one device selected from the group consisting of: the electromagnetic trigger (581), the electromagnetic valve (503), the first servo (180), the second servo (150), the air compressor (700), and to the fan (136);
thereby to control operation of the system.

55. A method for dynamic solar energy utilization, the method comprising:
a) receiving solar energy from the sun by a solar receiver configured for receiving solar energy from the sun; the solar receiver comprising a plurality of flexible mirrors independent of each other and radially arranged around a main axis of the system, said plurality of flexible mirrors being configured to be either deployed for operation or collapsed and
b) concentrating the received solar energy at a predetermined spot area;
c) converting the concentrated energy into direct current electricity by a solar energy concentrator being located at the predetermined spot area in which the solar energy reflected from said plurality of flexible mirrors is concentrated.

56. The method according to claim 55, further comprising passing cooling air through the solar energy concentrator.

57. The method according to claim 55, further comprising sensing position of the sun in the sky by a solar tracking system and tilting the solar receiver for directing thereof towards the sun to receive and reflect maximum sunlight onto the predetermined spot area.

58. A method according to claim 55, further comprising folding at least one of said plurality of flexible mirrors under unfavorable environmental conditions.

59. A method according to claim 55, further comprising deploying at least one of said at least one of said plurality of flexible mirrors under favorable environmental conditions.

60. A method according to claim 55, further comprising inverting said DC electricity to AC electricity and providing said AC electricity into an electricity grid.
